(19) United States
(12) Patent Application Publication
(10) Pub. No.: US 2011/0210309 A1
(43) Pub. Date: Sep. 1, 2011

(54) TUBULAR NANOSTRUCTURES, PROCESSES OF PREPARING SAME AND DEVICES MADE THEREFROM

(75) Inventors: Moshit Ben-Ishai, Kfar-Saba (IL); Fernando Patolsky, Rechovot (IL)

(73) Assignee: RAMOT AT TEL-AVIV UNIVERSITY LTD., Tel-Aviv (IL)

(21) Appl. No.: 13/127,476

(22) PCT Filed: Nov. 4, 2009
(86) PCT No.: PCT/IL2009/001030

§ 371 Date: May 4, 2011

Related U.S. Application Data
(60) Provisional application No. 61/193,196, filed on Nov. 4, 2008.
(60) Provisional application No. 61/272,291, filed on Sep. 8, 2009.

(51) Int. Cl. H01L 29/66; H01L 21/20

(52) U.S. Cl. 257/9; 438/478; 257/E29.168; 257/E21.09

(57) ABSTRACT

Novel methods of producing single-walled and multi-walled, single-crystalline, tubular nanostructures, made of an inorganic substance (e.g., silicon), and single-walled and multi-walled, single-crystalline, tubular nanostructures produced thereby, are disclosed. Also disclosed are devices into which the nanostructures are integrated. The methods described herein are used to reproducibly and controllably producing single-crystalline nanostructures with well-defined shape, diameter and/or interwall distance, chemical composition and morphology.

### FIELD AND BACKGROUND OF THE INVENTION

The present invention, in some embodiments thereof, relates to nanostructures, and, more particularly, but not exclusively, to nanostructures such as nanotubes and nanocones, with controllable inner diameter, morphology, shape and chemical composition, to processes of manufacturing same and to uses thereof in applications such as nanoelectronics, nanophotonics and nanosensing.

Since the first report on the synthesis of carbon nanotubes almost two decades ago, extensive research efforts were invested in the preparation of various nanotubular materials.

The formation of tubular nanostructures generally requires a layered or anisotropic crystal structure. There are reports of nanotubes made from silica, alumina, silicon and other metals, which do not have a layered crystal structure, and which were synthesized by using carbon nanotubes and porous membranes as templates, or by thin-film rolling. These nanotubes, however, are either amorphous, polycrystalline or exist only in ultrahigh vacuum.

Silicon nanotubes have mostly been suggested theoretically due to the favorable formation of sp³ hybridization of Si in silicon nanotubes. Various processes of preparing silicon nanotubes have recently been reported.

For example, Schmidt and Eberl [Schmidt, O. G and Eberl, K., 2001 Nature 410: 168] have reported the synthesis of silicon/germanium nanotubes using a “role up” procedure in which a sacrificial layer of an etchant-sensitive material is deposited on a substrate surface, and a thin film (or a series of thin films) is deposited on the sacrificial layer. After selective etching of the sacrificial layer, the thin top layer is wrapped up and folded back onto the sample surface, where it can bond to itself. At the position where the layer bends, a nanotube is formed.

Sha et al. [Adv. Mater. 14:1219-1221, 2002] teach fabrication of silicon nanotubes using chemical vapor deposition (CVD) and a nanochannel Al₂O₃ substrate. In the methodology taught by Sha et al., gold is used as a catalyst and silicon atoms which enter the Al₂O₃ nanochannel substrate are deposited symmetrically on the wall of the channel. After deposition, the nanochannels are dissolved in HCl solution to thereby produce the silicon nanotubes.

Jeong et al. [Adv. Mater. 15:1172-1176, 2003] teach a process in which silicon nanotubes were grown on porous alumina surface, without the assistance of catalysts, using molecular beam epitaxy (MBE) methodology.

Both Sha et al. and Jeong et al. report of formation of disordered aggregation of silicon atoms inside the templates, which disrupts the formation of a well-defined crystalline structure of silicon.

Chen et al. [Adv. Mater. 17:564-567, 2005] teach a synthesis of silicon nanotubes, by a hydrothermal method, using SiO₂ powder as a starting material and de-ionized water as a reaction medium, without the assistance of catalysts. De Crescenzi et al. [Appl. Phys. Lett. 86:231901-1-231901-3, 2005] teach the fabrication of silicon nanotubes among the reaction products of a gas phase condensation synthesis, without using gas or metallic elements as catalysts.

The synthesis of monolayered nanotubes based on the use of core-shell nanowire templates, has been disclosed in U.S. Pat. No. 7,211,143. According to the teachings of this patent, uniform nanotubes are synthesized as sheaths over nanowire templates. An exemplary nanowire template taught by U.S. Pat. No. 7,211,143 includes hexagonal ZnO nanowires, onto which a thin GaN layer is grown, via epitaxial overgrowth in a chemical vapor deposition system. The ZnO nanowire template is subsequently removed by thermal reduction and evaporation, resulting in ordered arrays of GaN nanotubes on the substrate. Another exemplary nanowire template taught by U.S. Pat. No. 7,211,143 includes silicon (Si) nanowires which, upon being thermally oxidized, are sheathed by a thick layer of silicon oxide, to thereby form, upon dissolving the silicon, silica nanotubes.

The production of germanium (Ge) nanowires has been reported by, for example, Sun et al. [Nanotechnology 17, 2925-2930 (2006)], Dai and Wang [Angew. Chem. Int. Ed. 41, 4783-4786 (2002)], and Hong et al. [Angew. Chem. Int. Ed. 44, 2-5 (2005)]. Uses of germanium nanowires in applications such as field-effect transistors have also been reported [See, for example, Kim et al., Appl. Phys. Lett. 91, 033104-1-033104-3 (2007); and Greytak et al., Appl. Phys. Lett. 84, 4176-4178 (2004)].

Epitaxial core-shell heterostructures, including Ge—Si core-shell nanostructures, have also been reported [See, Lauhon et al., Nature 420, 57-61 (2002)]. According to this paper, germanium nanowires are produced via vapor-liquid-solid (VLS) growth process, and amorphous silicon is then grown on the nanowire by CVD. The amorphous silicon can then be converted to crystalline silicon by annealing at 600° C. The use of the formed heterostructures in the fabrication of coaxially gated nanowire field-effect transistor (FET) has also been described.

Multi-walled inorganic nanotubes [see, for example, Tenne, R. & Zettl, A. K. Carbon Nanotubes Topics in App. Physics 80, 81-112 (2001), as well as multi-walled carbon nanotubes (MWCNTs) and multi-walled silicon nanotubes, have also been studied.

Exemplary Background art related to single-walled and multi-walled silicon nanotubes include Zhang et al., in Chem. Phys. Lett. 364 (2002) 251; and in J. Phys. Chem. B 2005, 109, 8605-8612

Current methodologies for forming such multi-walled nanostructures result in nanostructures in which the interlayer distance is fixed and the composition of each wall cannot be individually controlled.

Current theoretical studied of silicon multi-walled nanotubes refer to silicon that have a SP² configuration.

### SUMMARY OF THE INVENTION

The production of silicon and other semiconducting nanotubes having controllable, defined and reproducible diameter, wall thickness, morphology, shape and chemical composition has never been described hitherto.

Growth of reproducible and controllable crystalline semiconductor nanotubes with uniform inner diameter, wall thickness, and controllable morphology, shape and chemical composition is highly advantageous in various applications, such as potential nanoscale electronics, biochemical-sensing applications and fluid transport devices (solution-based transistors).

The present inventors have now devised and successfully practiced a novel methodology for reproducibly producing semiconducting nanotubes having defined diameter, wall thickness, morphology, shape and chemical composition. Using this methodology, robust single-crystalline silicon nanostructures, with well-controlled and uniform inner diameter, wall thickness, taper angle and chemical composition were prepared. Multi-walled nanostructures have also been prepared.

According to an aspect of some embodiments of the invention, there is provided a multi-walled tubular nanostructure made of at least one single-crystalline inorganic substance, the nanostructure being characterized by an interwall distance between at least two walls which is smaller than 10 nm.

According to some embodiments of the invention, the nanostructure is characterized by an identical interwall distance between all of the walls or by a different interwall distance between at least two pairs of adjacent walls.

According to some embodiments of the invention, an interwall distance between two walls independently ranges from 2 nm to 100 nm.

According to some embodiments of the invention, the multi-walled nanostructure is being further characterized by a different wall thickness of at least two walls.

According to some embodiments of the invention, the multi-walled nanostructure is being further characterized by a different chemical composition of at least two walls.

According to an aspect of some embodiments of the invention, there is provided a multi-walled, tubular single-crystalline silicon nanostructure.

According to an aspect of some embodiments of the invention, there is provided a single-walled tubular nanostructure made of at least one single-crystalline inorganic substance, the nanostructure being characterized by an inner diameter which is either smaller than 5 nm or greater than 100 nm.

According to some embodiments of the invention, the nanostructure is generally shaped as a conical nanostructure.

According to some embodiments of the invention, the nanostructure is generally shaped as a “funnel-like” nanostructure;

According to some embodiments of the invention, the nanostructure further comprises at least one additional substance and/or is surface-modified.

According to some embodiments of the invention, any of the nanostructures described herein is further comprising a nanowire interposed within an inner wall of the nanostructure. According to as aspect of some embodiments of the invention there is provided a process of preparing such a nanostructure.

According to some embodiments of the invention, the single-crystalline inorganic substance is a semiconductor substance.

According to some embodiments of the invention, the single-crystalline inorganic substance is single-crystalline silicon.

According to an aspect of some embodiments of the invention, there is provided a method of producing single-walled or multi-walled tubular, inorganic, single-crystalline nanostructures, the method comprising: growing a nanowire made of a crystalline, sacrificial substance; epitaxially growing, onto the nanowire, a layer of an inorganic substance that has a crystallinity mismatch with the sacrificial substance of less than 4.5%; and etching the nanowire, thereby producing a single-walled tubular, inorganic, single-crystalline nanostructure, whereas when the nanostructure is a multi-walled nanostructure, the method further comprising, prior to the etching: growing onto the layer of the inorganic substance a layer of the sacrificial substance; epitaxially growing, onto the layer of the sacrificial substance, a layer of the inorganic substance; and repeatedly growing onto an outer layer of the inorganic substance a layer of the sacrificial substance; and growing onto the layer of sacrificial substance the layer of the inorganic substance; and whereas the etching comprises etching the nanowire and each of the layers of the sacrificial substance, the method being such that at least one of a shape, diameter, wall thickness and chemical composition of each wall is reproducibly controlled.

According to some embodiments of the invention, the inorganic substance is a semiconductor substance.

According to some embodiments of the invention, the semiconductor substance is silicon.

According to some embodiments of the invention, the sacrificial substance is germanium.

According to some embodiments of the invention, the method is further comprising, prior to the epitaxially growing the layer of the inorganic substance, reducing a diameter of the nanowire.

According to some embodiments of the invention, reducing the diameter is performed without affecting a crystallinity of the nanowire.

According to some embodiments of the invention, the sacrificial substance is germanium and wherein reducing the diameter is effected by thermal oxidation.

According to some embodiments of the invention, an average inner diameter of an inner wall of the nanostructures is smaller than 5 nm.

According to some embodiments of the invention, the method is further comprising, prior to epitaxially growing the layer of the inorganic substance, increasing an average inner diameter of the nanowires.

According to some embodiments of the invention, an average inner diameter of an inner wall in the tubular nanostructures is greater than 100 nm.

According to some embodiments of the invention, the method is further comprising, subsequent to epitaxially growing the layer of the inorganic substance, chemically modifying at least a portion of a surface of an outer layer of the inorganic substance.

According to some embodiments of the invention, the method is further comprising chemically modifying at least a portion of an internal surface of the nanostructures.

According to some embodiments of the invention, when the nanostructures are multi-walled nanostructures and wherein growing each of the layers of the sacrificial substance comprises a CVD performed at conditions that affect formation of a conformal, non-crystalline layer of the sacrificial substance.

According to some embodiments of the invention, the CVD is performed at a temperature of from 320° C. to 340° C.

According to some embodiments of the invention, the method is further comprising, subsequent to the CVD, annealing the conformal, non-crystalline layer of the sacrificial substance, to thereby obtain a layer of a single-crystalline sacrificial substance.

According to some embodiments of the invention, a thickness of each of the layers of the sacrificial substance independently ranges from 1 nm to 100 nm.

According to an aspect of some embodiments of the invention, there are provided single-walled inorganic, single-crystalline tubular nanostructures prepared by the method as described herein.

According to an aspect of some embodiments of the invention, there are provided multi-walled inorganic, single-crystalline tubular nanostructures prepared by the method as described herein.

According to an aspect of some embodiments of the invention, there is provided a device comprising the tubular nanostructure as described herein.

According to an aspect of some embodiments of the invention, there is provided an electric device, comprising the nanostructure as described herein, wherein the electric device comprises at least one of a transistor, a field effect transistor, an inverter, a switch and a sensor.

According to an aspect of some embodiments of the invention, there is provided a nanofluidic device, comprising the nanostructure as described herein, wherein the nanofluidic device comprises at least one of a nanofluidic transistor device, a liquid separator and a liquid analyzer.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods and examples are illustrative only and are not intended to be necessarily limiting.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIGS. 1A-H present a schematic illustration of a process of preparing single-walled Si nanotubes (FIG. 1A), according to some embodiments of the present invention, and structural characterization of the obtained Si nanotubes (FIGS. 1B-1H). FIG. 1B is a high resolution TEM (HRTEM) image of a representative single-crystalline Ge nanowire and its Fast Fourier transform (FFT) image (inset) showing (111) diamond-like crystalline planes of Ge with [111] growth direction. The oxide layer is about 1-2 nm. FIG. 1C is a HRTEM image of the junction between Ge-core (dark) and Si-sheath (light) which reveals compositionally sharp interface and continuing high-crystalline structure. The interplanar distance (0.20 nm) corresponds to (220) planes of Ge. Scale bar is 5 nm. The inset is a low resolution TEM image of the corresponding sample. Scale bar is 50 nm. The contrast clearly shows the core, the shell region and the interface. FIG. 1D is a HRTEM image of a representative single crystalline Si nanotube. The contrast reveals uniform crystalline hollow core and tube wall of about 5 nm. The lattice spacing correspond to (111) planes of Si. FFT of the image (upper inset of FIG. 1D) confirms that the nanotubes have diamond crystal structure of Si with [111] growth direction. A HRTEM image of the high quality crystalline wall of the corresponding Si nanotube is shown in the bottom inset of FIG. 1D. Scale bar is 5 nm. FIG. 1E presents a series of representative HRTEM images of single-crystalline Si nanotubes with uniform inner diameter of about 5 nm (left image), about 10 nm (middle image), and about 20 nm (right image), all having a uniform wall thickness of 5 nm and smooth surface. Scale bars are 5 nm for left image, and 10 nm for both middle and right image. The arrows highlight the hollow core region. Representative low resolution TEM images each nanotube are shown in the insets, and clearly illustrate the tubular structure. FIG. 1F presents a set of representative HRTEM images taken from the edge of the nanotube, demonstrating that all exhibit a uniform crystalline structure of Si, with uniform wall thickness of about 5 nm (left image), about 10 nm (middle image) and about 20 nm (right image). Scale bars are 4 nm, 5 nm and 10 nm, respectively. The arrows highlight the wall thickness region. FIG. 1G presents a plot showing the nanotube wall thickness as a function of the shell deposition time. FIG. 1H presents an energy dispersive X-ray spectra recorded along the longitudinal axis of a representative Si nanotube at different sites, which reveal a well correlated Si signal and a small residue of Ge (1-2%). The colored circles highlight the representative measured sites. Scale bar is 50 nm.

FIGS. 2A-C present Fast Fourier Transform (FFT) images of the HRTEM images presented in FIG. 1D, showing single-crystalline Si nanotubes with uniform inner diameter of about 5 nm (FIG. 2A), about 10 nm (FIG. 2B), and about 20 nm, and demonstrating a uniform diamond crystal structure of Si.

FIGS. 3A-C present Fast Fourier Transform (FFT) images of the HRTEM images presented in FIG. 1E, taken from the edge of a Si nanotube, demonstrating a uniform crystalline structure of Si, with uniform wall thickness of about 5 nm (FIG. 3A), about 10 nm (FIG. 3B) and about 20 nm (FIG. 3C).

FIGS. 4A-D present a schematic illustration of the synthesis (FIG. 4A) and structural characterization (FIG. 4B) of ultra-large inner diameter silicon nanotubes, according to embodiments of the invention, and a schematic illustration of the synthesis (FIG. 4C) and structural characterization (FIG. 4D) of ultra-small inner diameter silicon nanotubes. FIG. 4B presents a series of low resolution TEM images of representative single-crystalline Si nanotube with a uniform ultra-large inner diameter of 60 nm (1), about 100 nm (2) and about 400 nm (3). Scale bars are 20 nm, 50 nm and 100 nm, respectively. The bottom insets are representative low resolution TEM images of the corresponding Ge core-template after the enlargement process. Scale bars are 300 nm, 400 nm and 1000 nm, respectively. The upper inset in image (3) is a representative electron diffraction pattern of the nanotubes, confirming that the nanotubes have a single-crystalline structure of Si as indexed in this pattern. A HRTEM image of the sample presented in image (3) (FIG. 4B (4)) shows it exhibits uniform single crystalline structure with interplanar distance of 3.13 nm, corresponding to (111) crystal planes of the cubic diamond silicon structures. Scale bar is 5 nm. FIG. 4D (1) presents a HRTEM image of the Ge-core with diameter of about 20 nm. The white lines highlight the native oxide (GeO₂) layer of 1-2 nm. Images (2), (3) and (4) present a series of low resolution TEM images of Ge—GeO₂ core-sheath at different oxidation times of 5, 10 and 15 minutes, respectively. Scale bars are 10 nm for images (1), (2), (3), and 20 nm, for image (4). The inset in image (4) is a low resolution TEM image of a representative Si nanotube with inner diameter of about 1.5 nm and wall thickness of about 5 nm, recorded after evaporation of the GeO₂, deposition of Si shell and etching of the Ge core.

FIGS. 5A-D present a characterization of GeSi alloy nanotubes (FIG. 5A) and p-type doped nanotubes (FIGS. 5B, 5C and 5D). FIG. 5A presents a low resolution TEM image of a representative Si_{0.94}Ge_{0.06} alloy nanotube with uniform inner diameter of 20 nm, formed by subsequent introduction of GeH₄ during the shell growth process. Scale bar is 50 nm. A HRTEM of the nanotube edge (inset) shows a high-quality single-crystalline structure, with lattice spacing of 0.318 nm, corresponding to (111) crystal plane of Si with a cubic structure. FIG. 5B presents a representative low resolution TEM image of an in-situ p-type doped Si nanotube, which was formed by subsequent introduction of diborane during the Si shell growth. Scale bar is 200 nm. The inset shows a large magnification of the opened end of the nanotube. FIGS. 5C and 5D present compositional depth profiles on the nanotubes, probed by Time-Of-Flight Secondary Ion Mass Spectroscopy (TOF-SIMS) measurement, alongside sputtering process, which confirm the existence of the elements Si and B with nearly uniform atomic ratio of 1:200 B:Si.

FIGS. 6A-E present a schematic illustration of the synthesis (FIG. 6A) and structural characterization (FIGS. 6A and 6B) of conical silicon nanotubular structure, according to some embodiments of the invention, and a schematic illustration of the synthesis (FIG. 6D) and structural characterization (FIG. 6E) of ‘funnel’-like silicon nanotubular structures, according to some embodiments of the invention. FIG. 6B presents a set of representative scanning electron microscopy (SEM) images (1)-(4) of Ge-cone templates on a silicon substrate, showing the variation in the shape at different growth temperatures. The shape varies from a wire shape at 280° C., with a uniform diameter of 20 nm along the entire length (see image (1)), to conical shaped with various taper angles ranging from 1.8° at 340° C., to 2.5° at 360° C., and 4.2° at 380° C. (images (2), (3) and (4), respectively). Scale bars are 300 nm, 150 nm, 300 nm and 1 μm for images (1), (2), (3) and (4), respectively. A plot of the taper angle of the Ge-cone as a function of the temperature growth is shown in (5). The plot is constructed based on the statistical distributions of taper angle measured over 10 Ge cone nanowires at each growth condition of temperature (340° C., 360° C. and 380° C.). FIG. 6C presents TEM images of the Ge—Si core-shell conical nanowire and the resultant Si conical nanotubular structure. A low resolution TEM image of a typical Ge—Si core-shell cone grown at 380° C. is shown in image (1). Scale bar is 1 μm. A HRTEM image of the cone edge and its FFT (inset) is shown in image (2), showing that both Ge-core (dark) and Si-shell (bright) grow with a diamond crystal structure of Ge and along [111] growth direction. Scale bar is 5 nm. A low resolution TEM image which confirms the formation of a conical nanotubular structure with uniform sheath and smooth surface is shown in image (3). The upper right inset of image 3 presents the lattice resolved TEM image of the nanotubes and the lower right inset presents the FFT which demonstrates a uniform crystalline Si structures. Scale bars are 1.5 μm and 10 nm, respectively. FIG. 6E presents TEM images of a representative nanowire with a ‘funnel’-like shape: Low Resolution TEM image of a typical nanowire with a ‘funnel’-like shape is shown in upper part of image (1); Expanded images of the junction point between the wire and the cone, and the region of the wire growth from within the yellow rectangular and dark rectangular, respectively, are shown in the lower part of image (1). Scale bars are 600 nm and 300 nm, respectively. A low Resolution TEM of the obtained ‘funnel’-like nanotube is shown in image (2). Scale bar is 500 nm. A HRTEM of the sample in image (2) is shown in image (3) with its FFT (inset) pointing to a high quality single-crystalline structure of Si with [111] growth direction as indexed in the FFT image. Scale bar is 10 nm.

FIGS. 7A-B present a schematic illustration of a synthetic pathway used for functionalization of Si nanotubes by various silane derivatives (FIG. 7A), according to some embodiments of the invention, and images of the dispersions of the functionalized Si nanotubes in various solvents (FIG. 7B). Covalently linking aminosilane and phosphate-silane to Si nanotubes surface leads to Si nanotubes readily soluble in water (right images). Organic-soluble Si nanotubes were obtained by functionalization with fluorosilane (middle image) and octadecylsilane (left image).

FIGS. 8A-B present a scanning electron microscopy (SEM) image of a field effect transistor (FET) device fabricated from p-doped Si nanotubes according to some embodiments of the invention (FIG. 8A) (Scale bar 1 μm), and a plot showing the current recorded on a 20 nm internal diameter (10 nm wall thickness) of boron-doped Si nanotube (I) as a function of Voltage (V), at various gate voltages (V_{g}) of: −4V (pink), −2V (green), 0 V (yellow), +2V (red) and −4 V (blue) (FIG. 8B). The inset shows a transconductance curve at V_{sd}=+1 V. Scale bar is 1 μm.

FIGS. 9A-C present a schematic illustration of a process of preparing Si multi-walled (tube-in-tube) nanostructures according to some embodiments of the invention, in which growing Ge nanowires on a substrate (FIG. 9A) is followed by sequential deposition of Si layer, Ge layer and another Si layer, so as to obtain multi-walled Ge/Si/Ge/Si nanowires (FIG. 9B), and then by sonication and selective etching of Ge, so as to obtain a double-walled Si nanotube (tube-in tube) (FIG. 9C).

FIGS. 10A-F present images of intermediates en route the production of double-walled silicon nanotubes, prepared by an exemplary process according to embodiments of the invention. FIG. 10A presents a representative low resolution TEM (LRTEM) image on a scale bar of 40 nm; a high resolution TEM (HRTEM) image, on a scale bar of 4 nm. (top inset); and a fast Fourier transform (FFT) image (bottom inset) of a core (Ge)-shell (Si)-shell (Ge) nanowire (prior to depositing a Ge shell). FIG. 10B presents a LRTEM image, on a scale bar of 30 nm, of a core (Ge)-shell (Si)-shell (Ge) nanowire wherein the deposition of the Ge shell was carried out at 500° C., and at 380° C. (inset). FIG. 10C is a LRTEM image, on a scale bar of 200 nm, of a core (Ge)-shell (Si)-shell (Ge) nanowire wherein the deposition of the Ge shell was carried out at 330° C. Top inset is a LRTEM image, on a scale bar of 230 nm, showing the uniform, smooth and amorphous Ge-shell structure, and bottom inset is a HRTEM image, on a scale bar of 10 nm, further showing the uniform, smooth and amorphous Ge-shell structure. FIG. 10D is a LRTEM image, on a scale bar of 500 nm, of the nanowire shown in FIG. 10C, after being subjected to annealing at a fast heating rate of 10° C./seconds. Top inset is a HRTEM image, on a scale bar of 5 nm, showing an island of the same nanowire, exhibiting a polycrystalline structure. Bottom inset is a LRTEM image, on a scale bar of 500 nm, of a plurality of nanowires obtained. FIG. 10E is a LRTEM image, on a scale bar of 200 nm, of the nanowire shown in FIG. 10C, after being subjected to annealing with a gradual temperature rate of 10° C./10 minutes. Top inset is a HRTEM image, on a scale bar of 10 nm, of a the Ge shell. FIG. 10F is a LRTEM image, on a scale bar of 100 nm, taken after the deposition of a second Si shell on top of the annealed nanowire shown in FIG. 10C. Top inset is a HRTEM image, on a scale bar of 5 nm, revealing a crystalline Si shell. Bottom inset is a fast Fourier transform (FFT) image corresponding to the region shown in the top inset.

FIGS. 11A-D present a series of representative low-resolution TEM images of Ge(core)-Si—Ge(multishell) NW heterostructures grown from 20 nm-diameter AuNP, wherein the deposition of a Ge shell was performed at 330° C. and 100 Torr for 2 minutes (FIG. 11A), 4 minutes (FIG. 11B), 7 minutes (FIG. 11C) and 10 minutes (FIG. 11D), resulting in a GE shell having a thickness of 5, 10, 20 and 30 nm, respectively.

FIGS. 12A-D present a set of representative low-resolution TEM micrographs of Ge (core)-Si—Ge (multishell) NW heterostructures grown from AuNP of different diameters: 5 nm (FIG. 12A; scale bar of 10 nm), 10 nm (FIG. 12B; scale bar of 15 nm), 20 nm (FIG. 12C; scale bar of 25 nm) and 40 nm (FIG. 12D; scale bar of 50 nm), with a fixed Ge shell thickness of 30 nm. The arrows highlight the core size, showing a core (Ge)-shell (Si)-shell (Ge)-shell (Si) (multishell) nanowire heterostructure, wherein the deposition of a Ge shell was performed at 450° C. for 10 minutes.

FIGS. 13A-E presents a set of representative TEM micrographs of double-walled silicon nanostructures (DWSiNT-like structure) according to some embodiments of the invention. FIG. 13A is a LRTEM image, on a scale bar of 50 nm, of a DWSiNT-like structure with inter-wall distance of 2 nm and smooth and a uniform walls thickness of 4 nm. Top inset is a LRTEM image, on a scale bar of 50 nm, showing open-ended nanotube. The white circle highlights the walls of the nanotubular structure. Bottom inset is a LRTEM image, on a scale bar of 40 nm, showing the morphology of the corresponding core-multishell structure (prior to etching of the Ge layers). FIG. 13B is a LRTEM image, on a scale bar of 100 nm, of DWSiNT-like structure with inter-wall distance of about 10 nm. The inset is a LRTEM image, on a scale bar of 100 nm, of a corresponding core-multishell structure having a Ge-core size of 10 nm. FIG. 13C is a LRTEM image, on a scale bar of 60 nm, of DWSiNT-like structure with inter-wall distance of 30 nm. FIG. 13D is a LRTEM image, on a scale bar of 100 nm, of DWSiNTs-like structure with inter-wall distance of 60 nm. The inset is a LRTEM image, scale bar of 200 nm, of the corresponding template.

FIGS. 14A-F present a schematic illustration of silicon double-walled nanotube-based dual transistor electrical device, according to embodiments of the invention (FIG. 14A), an LRTEM image of the doped double-walled silicon nanotubes used for its formation, and electrical measurements performed with the device (FIGS. 14C-F). FIG. 14B is a LRTEM image, on a scale bar of 100 nm, of DWSiNT-like structure, in which the exterior wall is p-type doped and the interior wall is n-type doped. FIG. 14C are comparative plots presenting the current (I_{sd}) versus drain-source bias (V_{sd}) (output characteristics) of an outer p-type wall FET at gate voltages (V_{g}) of: −5V (red), −3V (purple), −1 V (blue), +1V (sky blue) +3 V (green) and +5 V (light purple). FIG. 14D is a plot showing the current variation as a function of the applied gate voltage (V_{g}) at constant V_{sd} of +5 V. FIG. 14E are comparative plots presenting the current (I_{sd}) versus drain-source bias (V_{sd}) (output characteristics) of an inner n-type wall FET at gate voltages (V_{g}) of: 5V (pink), 3V (red), 1V (blue), 0V (green), −1V (black), −3V (yellow), −5V (light blue). FIG. 14F is a plot showing the current variation as a function of the applied gate voltage (V_{g}) at constant V_{sd} of +1 V.

FIGS. 15A-B present a schematic illustration of a triple-walled nanotubular structure according to some embodiments of the invention (FIG. 15A) and its corresponding LRTEM image, on a scale bar of 100 nm (FIG. 15B). The top inset is a HRTEM image, on a scale bar of 20 nm, of the nanotube walls. The bottom inset is of LRTEM image, on a scale bar of 100 nm, of triple-walled SiNTs.

FIGS. 16A-B present a schematic illustration of a process of preparing hybrid silicon wire-in-tube nanostructures, according to some embodiments of the invention (FIG. 16A) and a LRTEM image, on a scale bar of 140 nm, of a silicon nanowire 80 nm in diameter within a uniform and smooth silicon nanotube (FIG. 16B). Bottom inset is a LRTEM image, on a scale bar of 240 nm, of the hybrid nanowire-in-nanotube with a silicon nanowire of 20 nm diameter. Upper inset is a LRTEM image, scale bar of 75 nm, of a Ge shell formed on top of Si nanowires at a temperature of 380° C.

FIG. 17A is a schematic illustration of an electronic device, according to some embodiments of the present invention.

FIG. 17B is a schematic illustration of two an electronic devices which can be used as an inverter, according to some embodiments of the present invention.

FIGS. 18A and 18B are schematic illustrations of junctions defined when two nanostructures are crossed, according to some embodiments of the present invention.

FIG. 19 is a schematic illustration of a nanofluidic transistor device, according to some embodiments of the present invention.

### DESCRIPTION OF SPECIFIC EMBODIMENTS OF THE INVENTION

The present invention, in some embodiments thereof, relates to nanostructures, and, more particularly, but not exclusively, to processes of producing single-walled and multi-walled nanostructures with well-controlled and uniform composition, dimensions and shape, to nanostructures formed thereby and to uses thereof in applications such as nanoelectronics, nanophotonics and nanosensing.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Nanowires and nanotubes are widely used for forming devices with intriguing mechanical, electrical and optical properties. The production of nanostructures with well-defined attributes, and with diverse functionalities, enables diverse architectures and thus, enhanced devices with diverse functions.

The production of silicon and other semiconducting nanotubes having controllable, defined and reproducible diameter, wall thickness, morphology, shape and chemical composition has never been described hitherto.

Growth of reproducible and controllable crystalline semiconductor nanotubes with uniform inner diameter, wall thickness and controllable morphology, shape and chemical composition is highly advantageous in various applications, such as potential nanoscale electronics, biochemical-sensing applications and fluid transport devices (solution-based transistors).

The present inventors have now devised and successfully practiced a novel methodology for reproducibly producing semiconducting nanotubes having defined diameter, wall thickness, morphology, shape and chemical composition. Using this methodology, robust single-crystalline silicon nanostructures, with well-controlled and uniform inner diameter, wall thickness, taper angle and chemical composition were prepared.

Thus, while reducing embodiments of the present invention to practice, nanotubular structures with uniform and controllable molecular-size inner diameters of less than 1.5 nm were synthesized. Robust and entirely hollow single crystalline Si nanotubes were formed from various tubular to conical structures, with uniform and well controlled inner diameter, ranging from 1.5 up to 500 nm and controllable wall thickness. Nanotubes doped in-situ with different concentrations of boron and phosphine to give p/n-type semiconductor nanotubes were also prepared. Alloy nanotubes were also prepared.

The synthetic approach of the present embodiments enables independent control of diameter, wall thickness, shape, taper angle, crystallinity and chemical/electrical composition of the obtained nanotubular structures. In accordance with some embodiments of the present invention, diameter and wall thickness of nearly any size can be obtained. This is advantageous over the traditional techniques since it allows to achieve high quality electronic materials and to tailor the tube properties to better-fit many biological, chemical and electrical devices applications. This level of control over the nanotubes parameters has never been taught hitherto.

The present inventors have further devised and successfully prepared and practiced a novel method of preparing single-crystalline multi-walled nanostructures. More specifically, the synthesis of hybrid tubular nanostructures such as, for instance, “tube-in-tube” and “wire-in-tube” nanostructures for which the dimensions, including the interwall distance and chemical composition of each wall may be individually controlled is presented herein for the first time, in accordance with some embodiments of the present invention.

Thus, the walls of these multi-walled tubular nanostructures can be readily and differentially doped in situ with different dopants to form nanostructures with multiple built-in electrical properties. In some embodiments, Si/Ge core-multishell heterostructures are used as a template for producing, for example, silicon multi-walled nanostructures. The formation of smooth and uniform Ge shells on both Si cores and Ge(core)-Si(shell) structures, in a layer-by-layer mode, is performed with no limiting dimensions. In some embodiments, wire-in-tube nanostructures are formed with different controlled core diameters and with variable distance between the nanowire core and the nanotubular walls.

The multi-walled and hybrid nanostructures described herein open the opportunity to fabricate novel nanoscale electrical and optoelectrical devices. In some embodiments, these multi-walled or hybrid nanostructures are used in the fabrication of novel filed effect transistor (FET) devices of dual electrical performance. Accordingly, the nanostructures presented herein can be used to fabricate nanoscale devices of higher complexity, which cannot be achieved by using currently known nanostructures.

In some embodiments of the present invention, the multi-walled nanostructures are formed with uniform and well controlled interwall distance, ranging from 1 nm up to 100 nm, and with controllable wall thickness.

In some embodiments of the present invention, the multi-walled nanostructures can be tubular, conical or both (“funnel-like”). Controlled doping of selected walls s is also contemplated. For example, in-situ doping with different concentrations of boron and phosphine, each applied to a different wall provides p/n-type semiconductor multi-walled nanostructures. Alloy multi-walled nanostructures are also prepared. The synthetic approach of the present embodiments enables independent control of diameter, wall thickness, shape, taper angle, crystallinity and chemical/electrical composition of the obtained multi-walled nanostructures.

The single-walled and multi-walled tubular nanostructures, in accordance with some embodiments of the present invention, may be produced with dimensions such as, for instance, an inner diameter, an interwall distance and a wall thickness of nearly any size.

As used herein throughout, the term “nanostructure” relates to objects having nanoscale dimensions, e.g., dimensions ranging from 0.1 nm to 1000 nm. The phrase “tubular nanostructure” relates to nanostructures, as defined herein, which are shaped as hollow tubes, preferably entirely hollow along their longitudinal axis. The phrase “tubular nanostructure” is also referred to herein interchangeably as “nanotubes” or as “nanotubular structure”.

Herein throughout, wherever a nanostructure is described, a plurality (collection) of such nanostructures is also contemplated. In some embodiments, at least a few of the nanostructures in the collection have the characteristics described for the nanostructure.

By “at least a few” it is meant at least 20%, at least 30%, at least 40%, at least 50%, at least 60%, at least 70%, and preferably at least 80%, at least 90%, at least 95%, at least 98% and even 100% of the collection of nanostructures.

According to an aspect of some embodiments of the invention there is provided a method (also referred to herein as “process”) of producing tubular, inorganic, single-crystalline single-walled nanostructures. The method is effected such that at least one of a shape, diameter, wall thickness and/or chemical composition of the produced nanostructures is reproducibly controlled. In some embodiments, the method is effected such that each of the shape, diameter, wall thickness and/or chemical composition of the produced nanostructures is independently reproducibly controlled. The method described herein can therefore be used, for example, for mass production of nanostructures with uniform, yet versatile, characteristics.

It is to be understood that, unless otherwise defined, the operations described hereinbelow can be executed either contemporaneously or sequentially in many combinations or orders of execution. For example, two or more operations, appearing in the following description in a particular order, can be executed in a different order (e.g., a reverse order) or substantially contemporaneously. Additionally, several operations described below are optional and may not be executed.

The method, according to this aspect of embodiments of the invention, is effected by growing a nanowire made of a crystalline, sacrificial substance; epitaxially growing, onto the nanowire, a layer of an inorganic substance that has a crystallinity mismatch with the sacrificial substance of less than 4.5%; and etching the nanowire template.

Selecting a couple of a sacrificial substance and an inorganic substance for forming the nanostructure with the indicated crystallinity mismatch allows the epitaxial growth of a layer of single-crystalline inorganic substance onto the sacrificial nanowire, while circumventing the need to perform further procedures so as to achieve a desired crystallinity.

The phrase “crystallinity mismatch”, also referred to interchangeably herein and in the art as “lattice mismatch”, and is defined by:

Lattice mismatch=(Lattice constant of film/lattice constant of substrate)−1

Wherein the substrate corresponding to the sacrificial substance described herein and the film corresponds to the inorganic substance described herein.

In addition to the crystallinity parameter, which defines a sacrificial substance of choice according to the desired inorganic substance for forming the nanostructures, the sacrificial substance is selected such that it can be selectively removed at the end of the production process.

Exemplary sacrificial substances include, but are not limited to, zinc oxide (ZnO), zinc sulfide (ZnS), silicon (Si), gallium nitride (GaN), germanium (Ge), silver (Ag), gold (Au), a Group II-VI element, a Group III-V element, and a Group IV element, as long as the above-indicated crystallinity and susceptibility to selective etching are met.

The nanowire described herein throughout is also referred to herein as a “core”, and/or a “template”.

The phrase “inorganic substance” is used herein to describe non-carbon substances. Accordingly, the nanostructures described herein throughout do not include carbon nanotubes or any other carbon nanostructures.

In some embodiments, the inorganic substance is a metal, a semi-metal, a metal salt, a metal oxide, a metal nitride, a metal phosphide, a metal sulfide, a metal carbide, a metal arsenide, and the likes, a metal alloy, and any combination of the forgoing.

In some embodiments, the inorganic substance is a semiconductor substance. Exemplary semiconductor substances that are suitable for use in embodiments of the invention include, but are not limited to, silicon (Si), gallium nitride (GaN), titanium (Ti), bismuth (Bi), tellurium (Te), lead (Pb) silicon carbide (SiC), gallium arsenide (GaAs), gallium phosphide (GaP), indium phosphide (InP), indium arsenide (InAs), aluminum nitride (AlN), zinc oxide (ZnO), zinc sulfide (ZnS), indium oxide (InO), indium tin oxide (ITO) and cadmium sulfide (CdS).

Semiconductor substances are desired for forming nanostructures that can integrated in potential nanoscale electronics, biochemical sensing applications and fluid transport devices (e.g., solution-based transistors), as well as in other various applications, as further described in detail herein.

According to some embodiments of the invention, the semiconductor substance is silicon. Silicon nanotubes are highly suitable for integration in circuits used in microelectronic systems.

According to some embodiments of the invention, the sacrificial substance is germanium.

The usage of germanium as a sacrificial substance offers the following advantages: It can be etched away selectively either by wet chemical etching or by thermal oxidation, such that the etching by both mechanisms does not affect the integrity and the crystallinity of the nanostructures formed. The selective etching of Ge over Si is particularly useful for Si nanostructures. Different etchants are known to effectively and selectively remove germanium.

According to some embodiments of the invention, the sacrificial substance is germanium and the inorganic substance is silicon. As demonstrated in the Examples section that follows, the method described herein was successfully practiced using a germanium-silicon couple. Alternatively, in optional embodiments, the sacrificial substance is silicon and the inorganic substance is germanium. The silicon-germanium couple has a crystallinity mismatch of 4.2%.

As discussed in the Background section hereinabove, some methodologies which utilize a silicon-germanium couple have recently been reported. Other methodologies for producing silicon nanotubes have also been reported. Yet, these methodologies fail to produce reproducibly single-crystalline silicon nanotubes.

Other couples of a sacrificial substance and an inorganic substance that are suitable for use in the context of embodiments of the invention include, but are not limited to, silicon-ZnS and germanium-ZnS, each of the silicon, germanium and ZnS can serve either a sacrificial substance or as an inorganic substance for forming the nanostructures.

According to some embodiments of the invention, growing the nanowire is performed on an inert substrate. Exemplary substrates include, but are not limited to, silicon wafers.

According to some embodiments of the invention, subsequent to the epitaxially growing the layer of the inorganic substance the inert substrate is removed. Alternatively, the inert substance is removed subsequent to etching the sacrificial substance. Once the substrate is removed, the formed nanostructures remain intact.

According to some embodiments of the invention, growing the nanowire is effected in the presence of nanoclusters (or nanoparticles), which serve for catalyzing the nanowire growth. Accordingly, in some embodiments, the method described herein is effected by depositing onto the substrate nanoclusters that are suitable for catalyzing the nanowire growth. Thus, in some embodiments, the inert substrate has nanoclusters dispersed thereon, the nanoclusters being for catalyzing the growing of the nanowire template. In some embodiments, the nanoclusters are deposited on the substrate from a colloidal solution.

The nanoclusters are selected in accordance with the sacrificial substance used, so as to effectively catalyze growing of a single-crystalline nanowire. Selecting nanoclusters suitable for catalyzing the nanowire growth are within the capabilities of those skilled in the art of material science and nanotechnology.

The size of the nanoclusters determines the initial diameter of the formed nanowire. In some embodiments, the initial diameter of the nanowire determines the inner diameter of the formed nanostructure. As detailed hereinbelow, in some embodiments, the initial diameter is further manipulated so as to obtain nanostructures with an inner diameter different than the size of the nanoclusters used.

In some embodiments, the nanoclusters are gold nanoclusters. In some embodiments, the nanoclusters (e.g., gold nanoclusters) have a diameter that ranges from 5 nm to 50 nm. In some embodiments, the nanoclusters (e.g., gold nanoclusters) have a diameter of about 20 nm.

It is noted that growth of nanowires from large gold seeds particles (d≧50 nm) may in some cases produce nanowires in low yields at low growth temperature or to overproduce nanowires at high temperatures, due to splitting of the gold seeds during, for example, a VLS procedure used for growing the nanowire [Hong et al. Angew. Chem. Int. Ed. 44, 2-5 (2005)]. On the other hand, small gold seeds (d≦5 nm) may in some cases lead to nanowires growth with a diameter that is larger than that of the initial particles, a result of the combination of axial and radial growth.

According to some embodiments of the invention, growing the nanowire template is effected via a vapor-liquid-solid (VLS) technique.

In some embodiments, the VLS mechanism is coupled with a chemical vapor deposition, so as to effect nanowire growth. In some embodiments, nanowire growth is effected in an ultra high vacuum chemical vapor deposition (UHV-CVD) system.

The conditions used to effect nanowire growth can be manipulated so as to affect the shape of the resulting nanostructure.

According to some embodiments of the invention, the tubular nanostructures can be, for example, cylindrical nanostructures, conical nanostructures and funnel-like nanostructures.

According to some embodiments of the invention, growing the nanowire comprises a chemical vapor deposition (CVD) performed at conditions that affect axial growth of the nanowire.

In embodiments where the sacrificial substance is germanium, the CVD is performed at a temperature of from 270° C. to 290° C. In some embodiments, CVD is performed at 280° C. It is noted that the CVD temperature used for growing the nanowire may affect the crystallinity of the obtained nanostructures, such that, for example, at lower or higher temperatures, an amorphous morphology is obtained, requiring a further procedure of annealing. For example, Lauhon et al., Nature, Vol. 420, 2002, have prepared Ge—Si multishell nanowires by growing Ge core nanowire at 380° C., to affect radial growth and have obtained an amorphous silicon shell.

In some embodiments, for any sacrificial substance used, CVD is performed at a temperature that results in axial growth of the nanowire, and in any event, that does not result in radial growth.

According to some embodiments of the invention, the CVD is performed using germane (GeH₄ as a precursor), in a hydrogen carrier.

The amount of germanium can be manipulated by the concentration of the precursor in the carrier, the carrier flow and/or the pressure at which the procedure is effected.

In some embodiments, CVD is performed using 10% germane in 200 sccm H₂ and 400 Torr.

According to some embodiments of the invention, growing the germanium nanowire further comprises, prior to the CVD, a preliminary CVD, in order to effect nucleation. In some embodiments, this procedure is performed at a temperature of 315° C. Other temperatures in the ranges of ±20° C. can also be used.

Using the above conditions, axial growth of the nanowire is effected, resulting in a cylindrical nanowire. The shape of the formed nanowire dictates the shape of the resulting nanotube. Hence, according to some embodiments of the invention, the tubular nanostructures are generally cylindrical tubular nanostructures.

According to some embodiments of the invention, growing the nanowire comprises a chemical vapor deposition (CVD) performed at conditions that affect conformal growth of the nanowire.

In some embodiments, in cases where the sacrificial substance is germanium, the CVD is performed at a temperature higher than 300° C., so as affect conformal growth of the nanowire.

According to some embodiments of the invention, the CVD is performed using 10% germane in 200 sccm H₂ and 400 Torr. Other parameters are also contemplated, as discussed herein.

According to some embodiments of the invention, conformal growing the germanium nanowire further comprises a preliminary CVD, performed at a temperature of 315° C., as described herein, to affect nucleation.

According to some embodiments of the invention, performing the CVD as described in these embodiments, such that a conformal growth of the nanowire is effected, results in tubular nanostructures which are generally conical tubular nanostructures.

According to some embodiments of the invention, a taper angle of the conical nanostructures ranges from 1° to 10°.

According to some embodiments of the invention, a taper angle of the conical nanostructures ranges from 1.5° to 5°.

The taper angle of conical nanostructures described herein can be manipulated and finely controlled by manipulating the conditions ate which CVD is performed, as exemplified, for example, in the Examples section that follows.

According to some embodiments of the invention, growing the nanowire template comprises a first chemical vapor deposition (CVD) performed at conditions that affect conformal growth of the nanowire, followed by a second chemical vapor deposition (CVD) performed at conditions that affect axial growth of the nanowire. Growing the nanowire under such conditions results in nanostructures which are generally “funnel-like” tubular nanostructures.

According to some embodiments of the invention, the sacrificial substance is germanium and the first CVD is performed so as to affect conformal growing of the nanostructure, as described herein. Similarly to the growing of conical nanowires described herein, the taper angle of the conical part of the “funnel-like” nanostructures described herein can be finely-controlled.

According to some embodiments of the invention, the sacrificial substance is germanium and the second CVD is performed so as to affect axial growing of the nanostructure, as described herein.

Once a nanowire with defined shape and crystallinity is obtained, a layer of the inorganic substance of choice is grown on the nanowire.

As discussed hereinabove, the sacrificial substance, the inorganic substance and optionally the process parameters for growing the layer of the inorganic substance affect an epitaxial growth of the layer of the inorganic substance.

By “epitaxial growth” or “epitaxially growing” it is meant that a crystalline layer of one substance (herein the inorganic substance) is grown on top of an existing single-crystalline base (herein the nanowire made of the sacrificial substance) in such a way that its crystalline orientation is the same as that of the base.

Vapor phase epitaxy is one of the most common processes for epitaxial layer growth. Any of the known techniques for vapor phase epitaxy can be used in these embodiments. In some embodiments of the invention, epitaxially growing the layer of the inorganic substance is effected by CVD.

In some embodiments, epitaxial growth is effected by selecting a sacrificial substance and an inorganic substance as described herein that have a crystallinity mismatch of less than 4.5%, as described herein.

In some embodiments of the invention, the second substance is silicon and the CVD is performed using silane in a mixture of H₂ and Ar.

According to some embodiments of the invention, the CVD is performed using 5 sccm silane in a mixture of 10 sccm H₂ and 5 sccm Ar, at 1 Torr.

According to some embodiments of the invention, the CVD is performed at a temperature that ranges from 440° C. to 460° C. In some embodiments, the CVD is performed at a temperature of 450° C.

The wall thickness of the obtained nanostructures can be finely controlled by controlling the duration time of growing the layer of the inorganic substance.

Thus, according to some embodiments of the invention, the CVD is performed during a time period that ranges from 10 minutes to 200 minutes.

According to some embodiments of the invention, a corresponding thickness of the layer of the inorganic substance ranges from 1 nm to 50 nm.

According to some embodiments of the invention, the CVD is performed during a time period that ranges from 20 minutes to 120 minutes.

According to some embodiments of the invention, a corresponding thickness of the layer of the inorganic substance ranges from 5 nm to 20 nm.

As indicated hereinabove, the inner diameter of the produced nanostructures is dictated by the diameter of the nanowire template.

According to some embodiments of the invention, an average inner diameter of the tubular nanostructures ranges from 1 nm to 500 nm.

The initial diameter of the nanowire, in turn, is typically dictated by the diameter of the catalysts used for its growth.

The methodology described herein, however, can be effected by further controlling the diameter of the nanowire and thus further controlling the inner diameter of the formed nanostructure. As demonstrated in the Examples section that follows, nanostructures with ultrathin or ultralarge inner diameters have been reproducibly prepared.

The devised methodology enables to finely control the diameter of the nanowire, and hence, the formed nanostructures, without affecting the crystallinity of both.

Hence, according to some embodiments of the invention, the method further comprises, prior to the epitaxially growing the layer of the inorganic substance, reducing a diameter of the nanowire.

According to some embodiments of the invention, reducing the diameter is performed without affecting a crystallinity of the nanowire.

According to some embodiments of the invention, reducing the diameter is effected via thermal oxidation, etching or both.

For example, when the sacrificial substance is germanium, reducing the diameter can be effected by thermal oxidation, followed by etching of the formed oxide layer.

According to some embodiments of the invention, reducing the diameter comprises:

contacting the nanowire with oxygen, to thereby convert an external portion of the germanium to germanium oxide; and

etching the external portion of the germanium oxide.

According to some embodiments of the invention, the contacting of the nanowire with oxygen is effected at 250° C. and 1 Torr.

According to some embodiments of the invention, the contacting of the nanowire with oxygen is effected during 0.5-5 hours.

According to some embodiments of the invention, the contacting is effected during 1-3 hours.

According to some embodiments of the invention, the method further comprising, prior to the contacting, removing a native germanium oxide layer from the surface of the nanowire. As discussed in the Examples section that follows, this procedure may be desirable for obtaining desired characteristics.

Thermal oxidation followed by etching, or etching alone, can be utilized for forming nanowires with reduced diameter also for other sacrificial substances, as long as the procedure is performed at conditions that do not affect the crystallinity of the formed nanowire.

According to some embodiments of the invention, using the above methodology, nanostructures with an average inner diameter smaller than 5 nm, smaller than 4 nm, smaller than 3 nm and even smaller than 2 nm are obtained.

Alternatively, the method is effected by increasing the diameter of the formed nanowire, prior to epitaxially growing the layer of the inorganic substance, thereby increasing an average inner diameter of the formed nanostructures.

According to some embodiments of the invention, increasing the average inner diameter is performed by depositing an external layer of the sacrificial substance onto the nanowire.

According to some embodiments of the invention, the sacrificial substance is germanium and depositing the external layer is effected by CVD, at conditions that affect radial growth of the external layer. According to some embodiments, the selected conditions do not affect the crystallinity of the formed nanowire

According to some embodiments of the invention, using this methodology, nanowires (and the formed nanostructures) with an average inner diameter greater than 100 nm, greater than 200 nm, greater than 300 nm and even greater than 500 nm are formed, regardless of the diameter of the nanoclusters used for growing the nanowire.

According to some embodiments of the invention, the chemical composition of the nanostructures is manipulated by epitaxially growing the layer of the inorganic substance in a presence of an additional substance, to thereby obtain tubular nanostructures which comprise a mixture of the inorganic substance and the additional substance.

Accordingly, nanostructures comprising an inorganic substance, mixed with an additional substance are formed. Various additional substances can be used and selected so as to affect the composition of the resulting nanostructures. In some embodiments of the invention, the additional substance is a semiconductor substance (e.g., an additional semiconductor substance in cases where the inorganic substance is a semiconductor substance), utilized for improving or controlling conductivity of the formed nanostructures. In some embodiments, the additional substance is a metal, such that the resulting nanostructures are formed from alloyed substance. In some embodiments, the additional substance is a p-dopant or an n-dopant, added so as to affect electrical performance of the formed nanostructures.

According to some embodiments of the invention, an atomic ratio between the semiconductor substance and the additional substance ranges from 100:1 to 10,000:1, or from 100:1 to 1,000:1.

According to some embodiments of the invention, the method further comprising, subsequent to epitaxially growing the layer of the inorganic substance, chemically modifying at least a portion of a surface of the layer of the inorganic substance.

According to some embodiments of the invention, the modifying is effected by covalently attaching a chemical substance to a functional group on a surface of the layer of the inorganic substance.

According to some embodiments of the invention, the modifying affects the hydrophillicity or hydrophobicity of the surface.

Thus, for example, once a layer of the inorganic substance is grown, controllably, chemical modification is effected by contacting the nanowires having deposited therein the layer of inorganic substance with solution containing a chemical substance, under conditions that allow attaching the chemical substance to a functional group of the inorganic substance. Such functional groups can be, as non limiting examples, hydroxyl groups present on the surface of silicon, and other substances, as a result of a native oxide layer; amine or phosphate groups similarly present on substances surface, and the likes, depending on the inorganic substance of choice.

The chemical substance of choice is selected so as to affect the chemical properties of the nanostructures surface. Thus, for example, a reactive alkyl (e.g., having 2-20 carbon atoms and a reactive group that can form a bond with the functional group on the inorganic substance surface) can be used to impart hydrophobicity to the formed nanostructures. Alternatively, the functional group or groups on the surface of the inorganic substance can be replaced by more hydrophilic groups, for example, by converting hydroxyl groups to phosphate groups.

A person skilled in the art could readily determine the chemical modification of choice and the chemical substances utilized to affect the desired surface modification.

Alternatively, according to some embodiments of the invention, the method further comprising, subsequent to removing the substrate, chemically modifying at least a portion of an internal surface of the nanostructures.

According to some embodiments of the invention, the modifying is effected by covalently attaching a chemical substance to a functional group on an internal surface of the nanostructures.

According to some embodiments of the invention, the modifying affects the hydrophillicity or hydrophobicity of the internal surface.

Thus, chemical modification can be effected prior to removing the substrate and/or prior to etching the sacrificial substance, so as to affect external surface modification, or subsequent to removing the substrate and to etching the sacrificial substance, so as to affect internal surface modification.

The conditions utilized for removing the substrate, so as to form intact nanostructures, and for etching the sacrificial substance can also be readily determined by a person skilled in the art, and include subjecting the formed core-shell structures to suitable chemical manipulations. Exemplary procedures are described in the Examples section that follows.

Herein throughout, the structure formed upon epitaxially growing a layer of an inorganic substance onto the nanowire described herein is also referred to as a core-shell nanostructure, wherein the core is the sacrificial nanowire and the shell is the inorganic substance.

In summary of the above-discussed embodiments of the invention, the methodology described herein comprises simple, effective and reproducible process for producing well-defined nanostructures, which is effected, according to some embodiments of the invention, mainly by placing an insert substrate of choice in a CVD system, and manipulating the CVD conditions and reagent compositions, so as to finely and reproducibly control the shape, morphology, diameter, and chemical composition of the obtained nanostructures. Further chemical manipulations, via, for example, wet chemistry, can be used for imparting additional properties to the formed nanostructures (e.g., via surface modification).

As discussed hereinabove, one of the advantages of the methodology described herein is the formation of single-crystalline tubular nanostructures with relatively small diameter.

According to an aspect of some embodiments of the invention there is provided method of producing tubular, inorganic, single-crystalline single-walled nanostructures having an average inner diameter smaller than 5 nm, the method comprising:

growing a nanowire template made of a crystalline, sacrificial substance, as described herein;

reducing the diameter of the nanowire template, as described herein;

epitaxially growing, onto the nanowire template, a layer of an inorganic substance that has a crystallinity mismatch with the sacrificial substance of less than 4.5%;

and etching the nanowire template, thereby producing tubular, inorganic single-crystalline, single-walled nanostructure with an average inner diameter smaller than 5 nm, as described herein.

According to some embodiments of the invention, reducing the diameter is performed without affecting a crystallinity of the nanowire.

According to some embodiments of the invention, reducing the diameter is effected via thermal oxidation, etching or both, as described herein.

According to an aspect of some embodiments of the invention there is provided method of producing tubular, inorganic, single-crystalline, single-walled nanostructures having an average inner diameter greater than 100 nm, the method comprising:

growing a nanowire template made of a crystalline, sacrificial substance, as described herein;

increasing the average inner diameter of the nanowire template, as described herein;

epitaxially growing, onto the nanowire template, a layer of an inorganic substance that has a crystallinity mismatch with the sacrificial substance of less than 4.5%;

and etching the nanowire template, thereby producing the tubular single-crystalline single-walled nanostructure having an average inner diameter greater than 100 nm, as described herein.

According to some embodiments of the invention, the inorganic substance is silicon, used to form advantageous single-crystalline silicon nanostructures, for integrating in various microelectronics, nanoelectronics, nanobiochemical applications.

Thus, according to an aspect of some embodiments of the invention there is provided a method of producing single-crystalline, single-walled silicon tubular nanostructures, the method comprising:

growing a nanowire template made of crystalline germanium, as described herein;

epitaxially growing a layer of silicon onto the nanowire template, as described herein;

and

etching the crystalline germanium, thereby producing crystalline silicon tubular nanostructures, the method being such that a shape, diameter, wall thickness and composition of the silicon nanostructures are reproducibly controlled.

In any of the methods described herein, chemical modification and surface modification of the formed nanostructures can be effected, as described herein.

According to an aspect of some embodiments of the invention there is provided a single-walled single-crystalline silicon nanostructure, prepared by the method described herein.

According to further aspects of embodiments of the invention there are provided single-walled, tubular, inorganic nanostructures, prepared by any of the methodologies described herein.

According to an aspect of some embodiments of the invention there is provided a single-walled tubular nanostructure (or a plurality of such nanostructures) made of at least one single-crystalline inorganic substance, as described herein.

In some embodiments, the nanostructure is characterized by an inner diameter smaller than 5 nm, optionally smaller than 4 nm, optionally smaller than 3 nm, and even smaller than 2 nm (e.g., of about 1.5 nm).

In some embodiments, the nanostructure is characterized by an inner diameter greater than 100 nm, optionally greater than 200 nm and even greater than 300 nm.

In some embodiments, the single-walled nanostructure is generally shaped as a conical nanostructure.

In some embodiments, the single-walled nanostructure is generally shaped as a “funnel-like” nanostructure.

In some embodiments, the single-walled nanostructure further comprises at least one additional substance, as described herein, mixed with the inorganic substance.

In some embodiments, the single-walled nanostructure is surface-modified, e.g., its external surface and/or internal surface, is modified by, for example, attaching a chemical substance to a functional group on the selected surface or surfaces.

The single-walled nanostructures described herein can also be referred to as N-walled nanostructures, wherein N equals 1.

In some embodiments, the single-walled nanostructure described herein is characterized by at least one of the following:

(i) a diameter of the nanostructure is smaller than 5 nm;

(ii) a diameter of the nanostructure is greater than 100 nm;

(iii) a shape of the nanostructure is of a conical nanostructure or of a “funnel-like” nanostructure;

(iv) a wall which comprises at least one additional substance; and

(v) at least a portion of a surface (internal or external) of the nanostructure which is chemical modified, all as described herein.

As discussed hereinabove and is further demonstrated in the Examples section that follows, utilizing the concept described herein for forming single-walled nanostructures, the present inventors have devised and successfully practiced a method of producing multi-walled single-crystalline inorganic nanostructures.

The multi-walled nanostructures described herein can also be referred to as N-walled nanostructures, wherein N is a positive integer greater 1.

The multi-walled nanostructures described herein are also referred to herein as “tube-in-tube” nanostructures or as multi-tube nanostructures. That is, the nanostructure is composed of an inner tube, which is interposed within another, greater (in diameter) tube, which is interposed within another, greater tube, and so on. Each of these tubes is referred to herein as a wall.

Accordingly, the phrase “multi-walled nanostructure”, is used herein to describe a nanostructure which comprises two or more walls, each wall being a hollow tubular nanostructure, as defined herein, wherein each tubular nanostructure is interposed within a consecutive larger tubular nanostructure.

In various exemplary embodiments of the invention at least two adjacent walls of the multi-walled nanostructure are separated by a gap along at least X % or their surface area, where X is 50 or 60 or 70 or 80 or 90. In some embodiments, X equals 100. The gap can be made of any fluidic material, namely gas (e.g., air) or liquid.

In some embodiments, the sizes of the gaps between adjacent walls in the multi-walled nanostructure are referred to as interwall distances, and describe the spatial distance between one wall to an adjacent wall, in terms of the differences in a diameter (or an average diameter) thereof.

The nanostructures of the present embodiments can also be elongated heterostructures of nanometric size, e.g., nanowire heterostructures or nanotube heterostructures.

The term “heterostructure” as used herein refers to a structure in which materials having different compositions meet at interfaces. The different compositions forming a heterostructure can be different materials and/or different doping levels or types. An “elongated heterostructure of nanometric size” means a heterostructures having the dimensions of a nanostructure as defined above.

The different compositions can be distributed along the longitudinal direction of the elongated heterostructure, in which case the heterostructure is referred to as “axial heterostructure”, or they can be distributed along the radial direction (e.g., forming a core with one or more shells), in which case the heterostructure is referred to as a “radial heterostructure.” Both axial and radial heterostructures are contemplated in various embodiments of the invention.

An interface between two different compositions in a heterostructure can form a p-n junction, when the composition on one side of the interface includes a p-doping and the other the composition on the other side of the interface includes a n-doping. In embodiments in which the heterostructure includes more than one p-n junction along its longitudinal dimension, it essentially comprises segments along its lengths that are different. For example, a heterostructure can have alternating portions that are differently doped and/or are made from different materials. For example, an elongated heterostructure can include a first heavily p-doped silicon segment, a second heavily n-doped GaN segment, and a third heavily n-doped silicon segment. Any other combination of doping and materials in an elongated heterostructure can be used. The length of the doped segments of an elongated heterostructure may or may not be uniform. The above combination is provided by way of example and a wide assortment of devices may be fabricated according to the techniques of the present embodiments. Various electronic devices, such as diodes, light emitting diodes, lasers, transistors, field effect transistors, and so forth can be produced in accordance with the teachings of the present embodiments.

Hence, according to an aspect of some embodiments of the invention there is provided a method of preparing a multi-walled single-crystalline inorganic nanostructure. The method described herein is such that that at least one of a shape, inner diameter, interwall distance, wall thickness and/or chemical composition of each wall of the produced nanostructures is independently and reproducibly controlled. In some embodiments, the method is effected such that each of the shape, inner diameter, interwall distance, wall thickness and/or chemical composition of each wall in the produced nanostructures is independently reproducibly controlled. The method described herein can therefore be used, for example, for mass production of multi-walled, optionally multi-functional nanostructures with uniform, yet versatile, characteristics.

In some embodiments, the method according to this aspect of the invention is effected by growing a nanowire made of a single-crystalline, sacrificial substance; epitaxially growing, onto the nanowire, a layer of an inorganic substance that has a crystallinity mismatch with the sacrificial substance of less than 4.5%; growing onto the layer of the inorganic substance a layer of the sacrificial substance; epitaxially growing, onto the layer of the sacrificial substance, a layer of the inorganic substance; and repeatedly growing onto an outer layer of the inorganic substance a layer of the sacrificial substance; and growing onto the layer of sacrificial substance the layer of the inorganic substance, so as to form a desired number of layers of the inorganic substance; and etching the nanowire template and each of the layers of the sacrificial substance.

The number of layers of the inorganic substance corresponds to the number of walls in the obtained multi-walled nanostructure.

According to some embodiments of the invention, growing a nanowire made of a single-crystalline, sacrificial substance; and epitaxially growing, onto the nanowire, a layer of an inorganic substance that has a crystallinity mismatch with the sacrificial substance of less than 4.5%, are each independently performed as described herein for single-walled nanostructures.

Accordingly, the shape (e.g., cylindrical, conical or “funnel-like”), inner diameter (e.g., reduced o increased), surface modification and any other parameters can be manipulated and performed as described herein for single-walled nanostructures. Thus, in some embodiments, the formed multi-walled nanostructures have a shape and an inner diameter as described herein for single-walled nanostructures.

Once a nanowire made of the sacrificial substance is grown and a first layer of an inorganic substance is epitaxially grown onto the nanowire, as described herein for single-walled nanostructures, a layer of a sacrificial substance is deposited onto the first layer of the inorganic substance.

The sacrificial substance used for forming this layer, and any other subsequent layers of a sacrificial substance can be the same as used for growing the nanowire template, or, can be another sacrificial substance. Similarly, two more types of a sacrificial substance can be used for forming corresponding two or more types of layers of sacrificial substances.

In some embodiments, the sacrificial substance used for forming the nanowire template and the sacrificial substance used for forming consecutive layers is the same, and is, for example, selected as discussed hereinabove for producing single-walled nanostructures.

According to some embodiments of the invention, growing each of the layers of the sacrificial substance is effected by using a CVD performed at conditions that affect formation of a conformal, non-crystalline layer of the sacrificial substance.

By “non-crystalline” it is meant that the morphology of the layer of the sacrificial substance formed is other than single-crystallinity, and can therefore be an amorphous morphology or of poor crystallinity.

As shown and discussed in the Examples section that follows, the non-crystalline morphology of the formed layer(s) of the sacrificial substance enables the formation of smooth, unstrained conformal layers of the sacrificial substance, without any constraints on either the thickness of the deposited layers or the inner diameter of the formed nanowire.

According to some embodiments of the invention, the sacrificial substance is germanium and CVD for depositing a layer of the sacrificial substance is performed at a temperature of from 320° C. to 340° C. These conditions can be further manipulated independently for each layer of the sacrificial substance deposited. In some embodiments, same conditions are used for depositing each of the sacrificial substance layers.

According to some embodiments of the invention, the method further comprises, subsequent to the CVD, annealing the conformal, non-crystalline layer of the sacrificial substance, to thereby obtain a layer of a single-crystalline sacrificial substance.

According to some embodiments of the invention, the annealing is performed at a temperature that ranges from 330° C. to 450° C.

Annealing can be performed during a pre-determined rate and time period, so as to achieve a desired morphology. For a detailed description and an exemplary procedure, see, the Examples section that follows.

According to some embodiments of the invention, the thickness of each of the layers of the sacrificial substance can be independently and finely controlled, by, for example, controlling the duration of time at which deposition of each layer is effected.

The thickness of each layer of the sacrificial substance determines the interwall distance between consecutive walls in the formed nanostructures, that is, the spatial distance between each two consecutive walls in the multi-walled nanostructure.

According to some embodiments of the invention, the thickness of each of the layers of the sacrificial substance independently ranges from 1 nm to 100 nm.

According to some embodiments of the invention, the thickness ranges from 2 nm to 60 nm.

Since the duration of time for depositing the layer of the sacrificial material can be readily determined, the method described herein can be readily utilized for forming multi-walled nanostructures with either identical or different interwall distances along the nanostructures (namely, between each pair of consecutive walls). Additionally, small interwall distances, of less than 10 nm, can be obtained.

Once a layer of a sacrificial substance is formed, another layer of an inorganic substance is epitaxially grown thereon. Epitaxially growing a layer of the inorganic substance can be effected as described herein for producing single-walled nanostructures.

Each of the layers of organic substances deposited on the nanowire core or on a layer of a sacrificial substance can comprise the same organic substance or different organic substances.

Similarly, the chemical composition of each of the layers of the inorganic substance can be manipulated as desired, by, for example, using an additional substance mixed with the inorganic substance during the growth of a particular layer, layers or in all layers, as desired.

Similarly, the wall-thickness of each wall can be independently determined as desired, by controlling the duration time of growing each layer of the inorganic substance.

Thus, multi-walled nanostructures with various functionalities can be obtained, such that each layer, or at least two layers in the formed multi-walled nanostructures, has a different chemical composition and/or thickness.

The additional substance can be as described hereinabove. Thus, for example, some layers of an inorganic substance can include a p-dopant and some can include an n-dopant, resulting in multifunctional structure.

Once sequential deposition of all sacrificial layers and layers of inorganic substances in completed, in some embodiments, removing the substrate is effected, followed by selective etching of sacrificial material(s). Etching can be effected as described hereinabove for single-walled nanostructures. If more than one sacrificial substances are used, consecutive etching procedures can be used, if required, to remove all sacrificial substances.

In any of the methods described herein, removing the substrate is effected by methods known is the art, depending on the substrate nature and nature of the nanostructures. In some embodiments, substrate in removed by sonication in a bath of an insert organic solvent.

The structures obtained prior to removing the substrate and the etching in the method of producing multi-walled nanostructures as described herein are also referred to herein as multishell nanowires, comprised of a nanowire core and consecutive shells of a sacrificial substance and epitaxially grown organic substance, as described herein.

The present embodiments also encompass these multishell nanowires.

Hence, in some embodiments, there is provided a nanostructure comprising a nanowire as described herein and a plurality of sequential layers of a sacrificial substance and an organic substance, as described herein. In some embodiments, such a nanostructure is composed of germanium as the sacrificial substance and of silicon as the inorganic substance. A Ge—Si core-multishell nanowire according to some embodiments of the invention, and its characterization, are described in detail in the Examples section that follows.

According to an aspect of some embodiments of the invention there is provided a multi-walled tubular, inorganic, single-crystalline tubular nanostructure prepared by the method as described herein.

According to an aspect of some embodiments of the present invention, there is provided a multi-walled tubular nanostructure made of at least one single-crystalline inorganic substance.

The multi-walled nanostructures described herein can include 2 walls and such are referred to herein as double-walled nanostructures. The multi-walled nanostructures described herein can include 3, 4, 5, 6, 7, 9, 10 and even more walls. Each of the walls can have a different chemical composition and/or wall thickness. The interwall distances between the walls can be the same or different for each two consecutive walls in the nanostructure, and can be as small as 10 nm and even smaller (e.g., 2 nm).

According to some embodiments of the invention, the multi-walled tubular nanostructure described herein is characterized by an interwall distance between at least two walls which is smaller than 10 nm.

According to some embodiments of the invention, the multi-walled tubular nanostructure described herein is characterized by an interwall distance between all of the walls which is identical. By “identical” it is meant ±1%.

According to some embodiments of the invention, the multi-walled tubular nanostructure described herein is characterized by an interwall distance between at least two pairs of adjacent walls which is different one from another.

According to some embodiments of the invention, the multi-walled tubular nanostructure described herein is characterized by an interwall distance between two walls that independently ranges from 2 nm to 100 nm.

According to some embodiments of the invention, the multi-walled tubular nanostructure described herein is characterized by a different wall thickness of at least two walls.

According to some embodiments of the invention, the multi-walled tubular nanostructure described herein is characterized by a different chemical composition of at least two walls.

According to some embodiments of the invention, the multi-walled nanostructure described herein is characterized by at least one of the following:

(i) an interwall distance between at least two walls which is smaller than 10 nm;

(ii) an interwall distance between at least two walls which is in a range of from 2 nm to 100 nm;

(iii) at least one wall which comprises at least one additional substance;

(iv) at least one wall which comprises one additional substance and at least one another wall which comprises another, different additional substance, such that at least two walls have a different chemical composition;

(iv) at least a portion of a surface (internal or external) of the nanostructure which is chemically modified;

(v) an identical interwall distance between all of the walls;

(vi) at least two walls that have a wall thickness that differ from one another; and

(vii) at least two different interwall distances between two pairs of adjacent nanotubes, all as described herein.

It is noted that a combination of any of the characteristics described herein is contemplated, as long as these characteristics do converge. Thus, for example, a multi-walled nanostructure can have identical interwall distances and different wall thicknesses and/or chemical compositions, but cannot have different interwall distances between two walls.

Thus, according to some embodiments of the invention, there is provided a multi-walled tubular nanostructure made of at least one single-crystalline inorganic substance, the nanostructure being characterized by an interwall distance between at least two walls which is smaller than 10 nm.

In some embodiments, the nanostructure comprises an identical interwall distance between all of the walls, and in some, other embodiments by a different interwall distance between at least two pairs of adjacent walls.

In some embodiments, an interwall distance between two walls independently ranges from 2 nm to 100 nm.

In some embodiments, the multi-walled nanostructure is characterized by a different wall thickness of at least two walls.

In some embodiments, the multi-walled nanostructure is characterized by a different chemical composition of at least two walls.

In some embodiments, the multi-walled nanostructure is surface-modified, as described herein for single-walled nanostructures.

According to another aspect of embodiments of the invention there is provided a multi-walled, tubular single-crystalline silicon nanostructure. The multi-walled silicon nanostructures described herein can have any of the characteristics described herein for multi-walled nanostructures.

According to some embodiments of the invention, each of the single-walled and multi-walled tubular nanostructures described herein further comprises a nanowire interposed within an inner tube in the nanostructure. Such nanostructures are also referred to herein a hybrid nanostructures or as “wire-in-tube” nanostructures.

An inner tube in referred to herein to describe the nanotube in a single-walled nanostructure or the inner tube in a multi-walled nanostructure.

The nanowire described in these embodiments of the invention is made of an inorganic substance, as described herein, which can be the same or different than the inorganic substance composing the tubular nanostructure.

It is noted that a nanowire is used herein to describe a non-hollowed nanostructure.

The nanowire is interposed within the inner tube such that there is spatial distance between the nanowire and the inner tube, similarly to the interwall distance as defined and described herein. The diameter of the nanowire and the spatial distance from the tube can be finely-controlled by preparing such a nanostructure.

Accordingly, a process of preparing a nanostructure comprising such a nanowire is also encompassed. The process is effected by growing a nanowire made of an inorganic substance; growing a layer of a sacrificial substance onto the nanowire; epitaxially growing a layer of an inorganic substance onto the layer of the sacrificial substance; and etching the sacrificial substance.

Growing the nanowire can be made as described for the sacrificial substance hereinabove. Similarly, growing the layers of the sacrificial substance and the inorganic substance can be effected as described hereinabove.

In some embodiments, growing a layer of a sacrificial substance onto the nanowire, and epitaxially growing a layer of an inorganic substance onto the layer of the sacrificial substance, can be performed repeatedly, as described herein for the multi-walled nanostructure.

It is noted that for any of the processes described herein, one can determine the conditions (e.g., technique, temperature, pressure, precursor, precursor concentration, carrier, etc.) as desired and/or as required by the desired substance to be deposited. Exemplary process conditions are described and discussed hereinabove and are exemplified in the Examples section that follows.

It is further noted that in any of the methods described herein, multi-segmented walls and/or multi-layered walls can also be formed. Accordingly, any of the nanostructures described herein can include one or more walls that are multi-segmented or multi-layered.

By “multi-segmented” it is meant that at least two segments along a longitudinal axis of the wall have a different chemical composition. An example is presented in Example 8 hereinbelow.

By “multi-layered” it is meant that a wall is comprised of one layer of one inorganic substance and a layer of another inorganic substance deposited therein, with no gap therebetween. Multi-layered walls can be produced simply by performing the epitaxial growth of the inorganic substance, as described herein, in two stages, one for each layer within the wall.

According to an aspect of some embodiments of the invention there is provided device comprising the tubular nanostructure as described herein.

Following are various applications incorporating the nanostructure of the present embodiments. In any of the embodiments described below, the nanostructure can be fabricated by the method described above or any other method such as a variant of the method described above.

A single nanostructure of the present embodiments can contact one or more additional components, depending on the application for which the nanostructures are prepared. The additional components can include contact pads, electrodes, supporting elements, fluid reservoirs and the like. The additional components can be deposited in any techniques known in the art, including, without limitation, lithography (e.g., electron-beam lithography and photolithography), and printing techniques (e.g., nano imprint lithography).

When one or more of the nanostructures are elongated axial heterostructures, a single heterostructure can contact a plurality of additional components, depending on the number of segments in the heterostructure. The lengths of the segments of a particular heterostructure can be approximately equal to the distance between the two adjacent additional components which the heterostructure contacts. For example, elongated heterostructure can contact several electrodes whereby the lengths of the segments equals the distance between the electrodes, or slightly longer than the distance between the electrodes. In this manner, a single p-n junction of the heterostructure is located between two electrodes.

The nanostructures and additional components can form an electric circuitry and/or nanofluidic network or system which can be utilized in various applications in the field of electronics and micro- or nanofluidics. For example, the nanostructures can be incorporated in an electric device such as, but not limited to, a transistor, a field effect transistor, an inverter, a switch and a sensor. The nanostructures can also be incorporated in a nanofluidic device, such as, but not limited to, a nanofluidic transistor device, a liquid separator and a liquid analyzer.

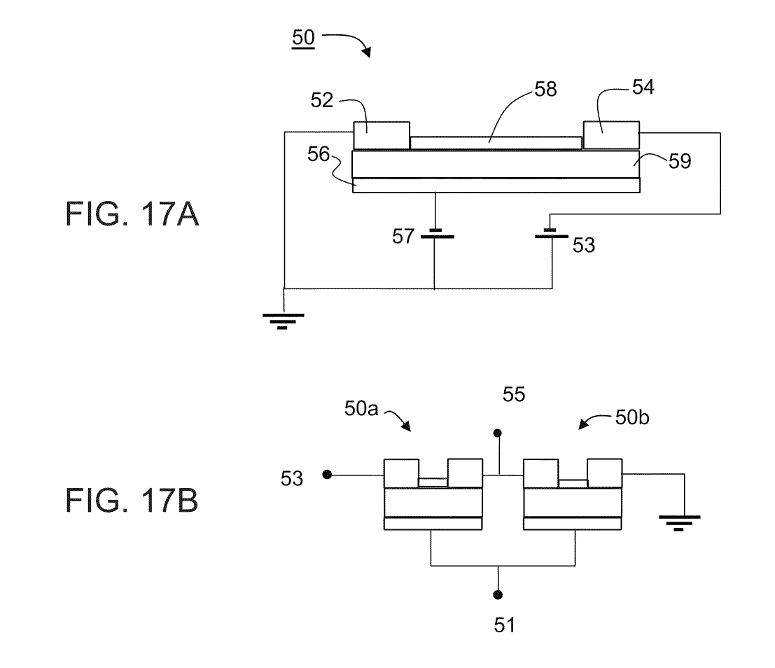

Reference is now made to FIG. 17A, which is a schematic illustration of an electronic device 50 which can be used for switching, inverting or amplifying, according to various exemplary embodiments of the present invention. Device 50 comprises a source electrode 52, a drain electrode 54, a gate electrode 56 and a channel 58. One or both of gate electrode 56 and channel 58 may be formed of a nanostructure made of a semiconductor material as further detailed hereinabove. For example, in one embodiment channel 58 is a nanostructure and gate electrode 56 is preferably layer of SiO₂ in a silicon wafer.

Device 50 can operate as a transistor, for example, a field effect transistor. Channel 58 has properties of a semiconductor material (either n-type or p-type properties) such that the density of charge carriers can be varied. A voltage 57 is applied to channel 58 through gate electrode 56, which is preferably separated from channel 58 by an insulating layer 59. When the voltage of gate electrode 56 is zero, channel 58 does not contain any free charge carriers and is essentially an insulator. As voltage 57 is increased, the electric field caused thereby attracts electrons (or more generally, charge carriers) from source electrode 52 and drain electrode 54, and channel 58 becomes conducting.

Thus, device 50 serves as an amplifier or a switching device in which, voltage 57 of gate electrode 56 controls the current flowing between source electrode 52 and drain electrode 54 when a bias voltage 53 is applied therebetween.

Two devices like devices 50 may be combined so as to construct an inverter. Referring to FIG. 17B, in this embodiment, a first such device (designated 50a) may include a channel having an n-type semiconducting properties and a second such device (designated 50b) may include a channel having a p-type semiconducting properties. Devices 50a and 50b are preferably connected such that when bias voltage 53 is applied between the source of device 50a and the drain of device 50b, the combined device serves as an inverter between input signal 51 and output signal 55.

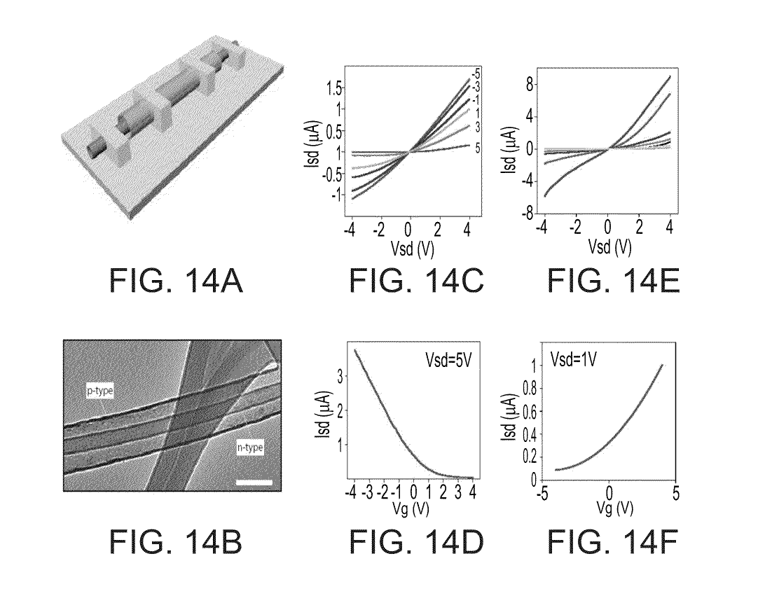

Combination of two or more such devices can also be archived in a generally concentric configuration, such as the configuration illustrated in FIG. 14A. In the representative example illustrated in FIG. 14A, the nanostructure has a core-shell structure wherein the length of the core is larger than the length of the shell, such that the core protrudes out of the shell in both sides. One pair of electrodes or contact pads is deposited on the protruding parts of the core to establish electrical contacts with the core, but not with the shell, and another pair of electrodes or contact pads is deposited on the shell but not with the core. Each pair serves as a source-drain pair and the device serves as a dual transistor device operating as described above

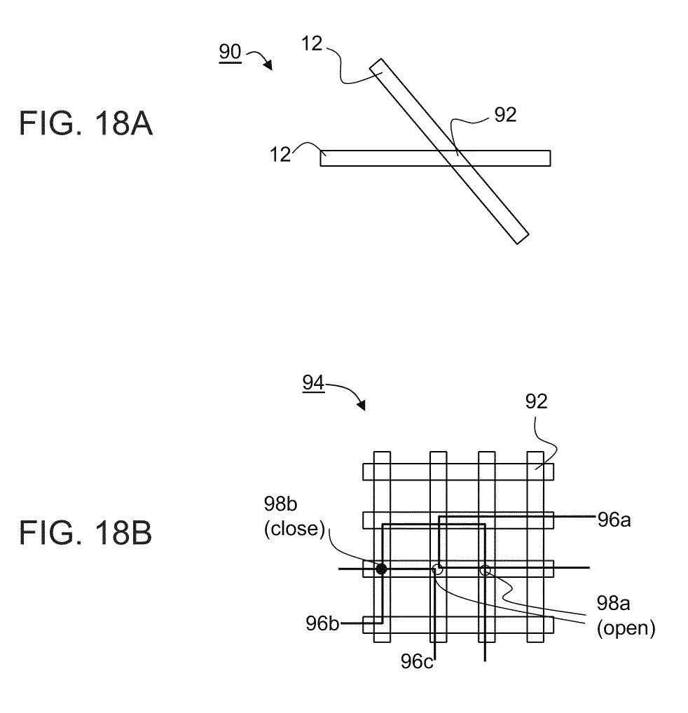

An additional configuration which includes the nanostructure of the present embodiments is illustrated in FIG. 18A. In this embodiment, two nanostructures 12 forming a junction 92 can serve as a transistor 90. Preferably, the semiconductor material of one of the two nanostructures has an n-type doping and the semiconductor material of the other nanostructure has a p-type doping.

In accordance with the present embodiments, one or both of nanostructures 12 of transistor 90, comprise or is made of a modulation-doped semiconductor material. One of nanostructures 12 can comprise the source and the drain portions of transistor 90 and the other nanostructure can induce the gate function at junction 92. Both pnp and npn transistors that are analogous to bipolar transistors may be formed in this fashion.

Several junctions like junction 92 can be allocated to form a crossbar array 94, which can be used for signal routing and communications between two layers of nanostructures. According to some embodiments of the present invention crossbar array 94 comprises a two-dimensional array of a plurality of junctions similar to junction 92. Each junction can serve as a switch. In one embodiment, at least one of the junctions is a quantum state molecular switch having an electrically adjustable tunnel junction between the respective two nanostructures. The switches, formed at each junction, can be electrochemically oxidized or reduced. Oxidation or reduction of the molecule forms the basis of a switch. Oxidation or reduction affects the tunneling distance or the tunneling barrier height between the two nanostructures, thereby exponentially altering the rate of charge transport across the junction.

Reference is now made to FIG. 18B which is a simplified illustration of array 94. Array 94 comprises a plurality of junctions 92 defined when two nanostructures 12 are crossed at some non-zero angle. When an appropriate voltage is applied across the nanostructures, molecules of each of the two nanostructures at the junction point are either oxidized or reduced. When a molecule of one nanostructure is oxidized, a molecule of the other nanostructure is reduced so that charge is balanced. These two species are referred to herein as a redox pair.

Distinct electrical circuits 96a and 96b and 96c may be created in array 94 as part of an integrated circuit. Circuits 96a, 96b and 96c can cross each other without being electrically connected where switches, shown as open circles in FIG. 18B and designated 98a, are open. Alternatively, the nanostructures may be electrically connected by a closed switch, shown as a filled circle in FIG. 18B and designated 98b. By using the voltage across the electrochemical cell formed by each pair of crossed nanostructures to make and break electrical connections both along nanostructures in a layer (segmented wires) and between wires in two layers (vias), one can create an integrated circuit of arbitrarily complex topology. The wires may connect to an external or an internal electronic device (not shown), e.g., a resonant tunneling diode or a transistor.

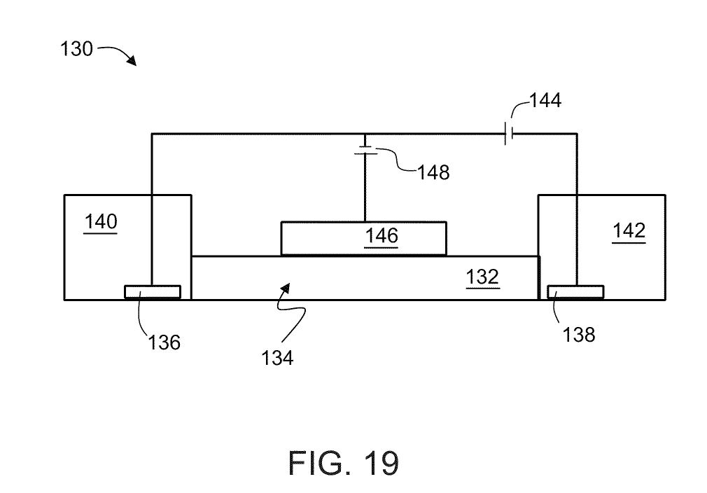

FIG. 19 is a schematic illustration of a nanofluidic transistor device 130 according to some embodiments of the present invention. Nanofluidic transistor device 130 can incorporate a nanostructures made of a semiconductor material, as further detailed hereinabove. The nanostructures is shown filled with an ionic solution 134 and coupled on both ends to fluidic reservoirs 140 and 142. One of reservoirs 140 and 142 serves as a fluid source and the other serves as a fluid drain. Device 130 preferably comprises a pair of source-drain electrodes 136 and 138. In the representative illustration of FIG. 19, source electrode 136 and drain electrode 138 are positioned at the bases of reservoirs 140, 142, respectively. However, this need not necessarily be the case, since, for some applications, it may not be necessary for the source and drain electrodes to be located on the bases of the reservoirs. In some embodiments of the present invention, the source and drain electrodes are in the reservoirs and contact the ends of the nanostructure, and in some embodiments the source and drain electrodes are attached directed to the exterior of the nanostructure near each end which facilitates current flow through the wall or walls of the nanostructure.

By applying a voltage bias 144 between source 136 and drain 138 electrodes, a current is induced between source 136 and drain 138 through nanostructure 132. An additional electrode 146 can be deposited to the external wall of nanostructure 132, preferably away from the ends of the nanostructure. Electrode 146 can serve as a gate electrode. A voltage bias 148 on electrode 146 blocks ion transport, thus acting like a valve between the reservoirs. For example, if biological molecules, which are generally charged, are introduced into the nanostructures, they are manipulated using the voltage bias on gate 146. Also contemplated is the use of multiple gates, such that ions and biomolecules can be manipulated spatially.

As used herein the term “about” refers to ±10%

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

As used herein, the singular form “a”, an and the include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

As used herein the term “method” refers to manners, means, techniques and procedures for accomplishing a given task including, but not limited to, those manners, means, techniques and procedures either known to, or readily developed from known manners, means, techniques and procedures by practitioners of the chemical, pharmacological, biological, biochemical and medical arts.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

### Material and Methods

Materials and Systems:

Gold nanoclusters were purchased from Ted Pella Inc. as a solution of nanoparticles with known diameter

Oxidized degenerately doped silicon wafer; oxidized (100) silicon wafers, copper grids; lacey copper grids were obtained from Silicon Quest International Inc.

Germanium (Ge); germane (GeH₄); silane (SiH₄), pentanol; diborane (B₂H₆); hydrogen peroxide (H₂O₂); ethanol; H₂ and Argon were obtained from Linde Germany Inc.

Chemical vapor deposition was performed using a home-built hot-wall chemical vapor deposition system.

Sample Characterization:

The obtained nanostructure samples were centrifuged, washed several times with ethanol and deposited on oxidized degenerately doped silicon wafer or copper grids or lacey copper grids for electrical transport and TEM measurements, respectively.

The structure and composition of the obtained nanostructures were investigated using 200 KV field emission gun transmission electron microscope (Technai F20).

The energy-dispersive X-ray spectra (EDX) were obtained using HRTEM with spot size of 2 nm.

TOF-SIMS analysis was conducted by PHI TRIFT II time-of-flight secondary ion mass spectrometer, on gold coated silicon wafer deposited with silicon nanotubes. The Ga⁺ primary ion beam was operated at 25 keV and 20 nA. Positive secondary ion spectra were acquired from 50×50 μm² areas of the surfaces. Sputtering was performed by Ge ions for 1 second followed by spectra acquisition. Sputtering area was: 150×150 μm².

Scanning electron microscopy (SEM) measurements were performed using a Jeol FEG-SEM instrument.

Devices Fabrication:

Heterostructured core-multishell Ge/Si nanowires were deposited on a highly-doped silicon substrate (<0.005 Ω/cm) with a 600 nm-thick silicon oxide (SiO₂) dielectric layer, and Ni/Au source-drain electrodes/contacts were formed thereafter by sequential e-beam lithography and germanium/silicon etching steps, respectively, in order to electrically address each silicon shell of the heterostructure. Once metal contacts were formed on each wall, the remaining germanium sections were removed selectively by immersion of the device substrate in a solution of hydrogen peroxide, as detailed herein. Annealing was then carried out by rapid thermal annealing (RTA) to form a stable, conducting silicide with a low Schottky barrier.

Transport characteristics were studied with the highly-doped silicon substrate serving as the back gate.

Electrical characterization was carried out by a cryogenic electrical probe station (Janis Inc. model TTP-4).

### Example 1

### Synthesis and Structural Characterization of Si Single-Walled Nanotubes

The Ge—Si core-shell nanowires were synthesized inside a horizontal quartz tube furnace at the CVD system, using gold nanoclusters as catalysts. The gold nanostructures were deposited on oxidized (100) silicon wafers.

Crystalline germanium nanowire-templates were grown on silicon wafers by the vapor-liquid-solid (VLS) mechanism, from Au nanoclusters, followed by conformal and epitaxial overcoating the cores with a silicon shell (and optionally various reactants/dopants, as detailed hereinunder), using a chemical vapor deposition system (CVD).

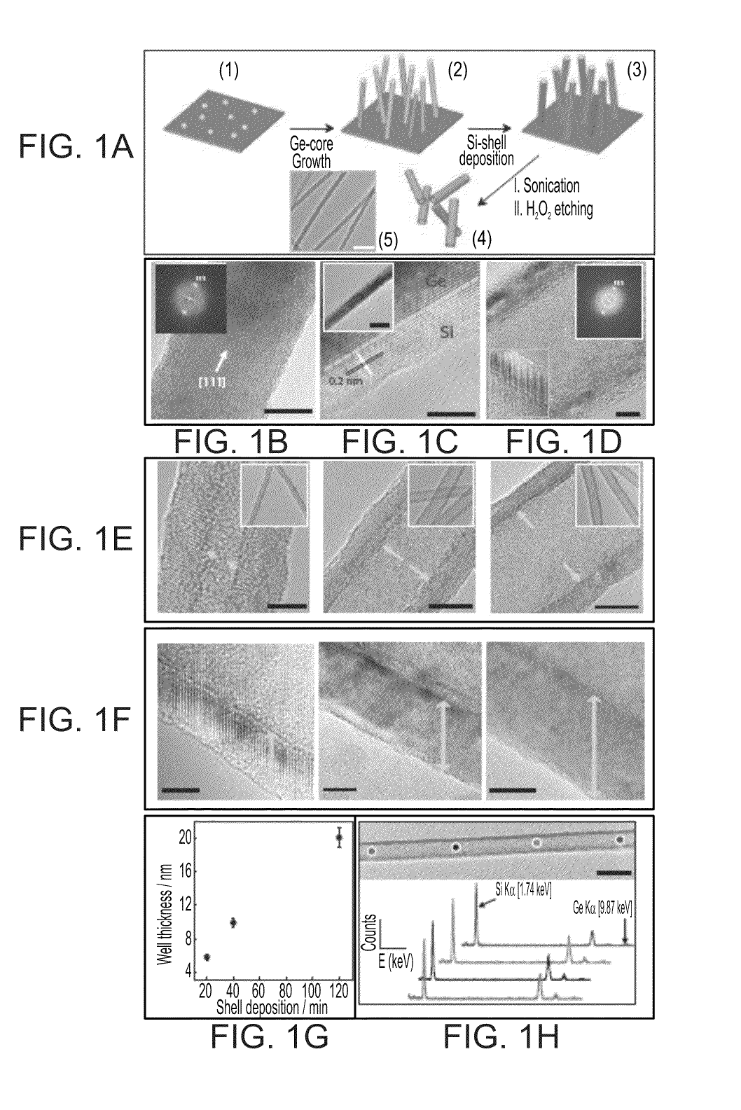

FIG. 1A presents a schematic outline of the general synthesis of silicon nanotubes by the nanowire-templating process, according to some embodiments of the invention.

The first step involves the deposition of Au nanoclusters from a colloidal solution with a desired diameter on a silicon wafer (1). The Au nanoclusters serve as seed particles for the Ge nanowire axial growth. The growth substrate is then placed in a chemical vapor deposition system, as described hereinabove, for the synthesis of the core (Ge)-shell (Si) nanowires. The diameter of the gold nanoparticles defines the diameter of the Ge core and the resultant silicon nanotubes' inner diameter.

The second step involves the formation of a Ge core template, using germane (GeH₄) as a precursor and H₂ as a carrier gas, in a two-step CVD process (2) [see, for example, Greytak et al. 2004, Appl. Phys. Lett. 84, 4176-4178]. The first CVD step is carried out at 315° C., using 15 sccm % germane in 90 sccm H₂ at 300 Torr, to form nucleation sites for the following axial core growth step. The axial core growth step occurs at a lowered temperature of 280° C., using 10% germane in 200 sccm H₂ and 400 Torr.

Thereafter, introduction of silane (SiH₄, 5 sccm) in a mixture of 10 sccm H₂ and 5 sccm Ar as a gas carrier, at 1 Torr, at an increased temperature of 450° C., is performed, in varying deposition times, leading to the conformal and epitaxial deposition of a Si shell on top of a Ge core (3).

The resulting core-shell nanowire heterostructures are sonicated off the growth substrate in a pentanol solution.

The etching step of the inner Ge-nanowire core is carried out in a solution of pentanol/30% hydrogen peroxide, 3:1 v/v %, at 60° C. for 2 hours. The resulting hollowed nanotubes (4) possess hydrophilic void, unfilled by pentanol. After removal of the Ge-template, the color of the solution turns from dark brown to brownish.

Alternatively, the core material is etched away by the thermal oxidation of Ge in the presence of O₂ at temperatures above 350° C., and the simultaneous vaporization of the obtained germanium oxide, to thereby obtain the hollowed silicon nanotubes.

Using the above methodology, Si nanotubes were successfully prepared. FIG. 1A (5) presents a low resolution TEM image of exemplary Si nanotubes obtained using the above-described methodology.

Characterization of the formed silicon nanotubes was carried out as described hereinabove. Some of the data are presented in FIGS. 1B-1H.

FIG. 1B shows a representative HRTEM image of high quality single-crystalline Ge nanowire grown by CVD, with a diameter of about 20 nm (including native oxide sheath of about 2 nm). The diameter of Ge nanowires grown without shells correlates well with the diameter of the Au nanocluster, with an average diameter of 20±4 nm measured for 40 wires that were grown from 20 nm nanoclusters. The HRTEM studies show that the obtained Ge nanowires have uniform structure and diameter along the entire length (greater than 10 μm) with a lattice spacing of 0.33 nm, which corresponds to the d-spacing of the (111) crystal planes of Ge with a cubic structure, indicating that the Ge nanowires have preferential growth orientation in the direction. The Fast Fourier transform (FFT) of the HRTEM image, shown in the inset of FIG. 1B, confirms that Ge nanowires grow with a diamond crystal structure and along the [111] direction.

The deposition of the Si shell at 450° C. on the Ge nanowires surface resulted in single-crystalline Ge—Si core-shell nanowire structures. FIG. 1C presents a HRTEM image (scale bar 5 nm) of a typical Ge—Si core-shell structure, and clearly shows a crystalline Ge core (dark) of about 20 nm and continuous, uniform crystalline Si shell (light) of about 5 nm along the entire length of the nanowire. As further shown in FIG. 1C, the core/sheath interface is compositionally sharp and no oxide layer was detected at the interface. As can be further observed in FIG. 1C, a layer of about 1 nm amorphous SiO₂ covers the nanowire surface, exhibiting an atomically interface which is presumably formed when the nanowires were exposed to ambient environment, similarly to the previously reported oxide sheathing of silicon nanowires [see, Hofmann et al. 2003, J. Appl Phys. 94: 6005-6012]. As can be further observed in FIG. 1C, both the core and the shell regions have lattice spacing of 0.20 nm which is in agreement with the (220) planes of the known diamond crystal structure of Ge. This observation indicates a continuous epitaxial layer of Si on the Ge core surface, without post growth annealing process. The inset of FIG. 1C presents a low resolution TEM image of the corresponding sample, on a scale bar of 50 nm.

In addition, energy dispersive X-ray spectroscopy (EDX) measurements confirmed the existence of the elements Ge and Si with nearly uniform atomic ratio of 1.04:1.00 (data not shown).

By selective etching of the Ge core, as described hereinabove, the Ge—Si core-shell nanowires were successfully transformed into crystalline Si nanotubes. FIG. 1D presents a representative HRTEM micrograph of a typical Si nanotube, on a scale bar of 5 nm, and shows that the obtained nanotubes have uniform and high quality single-crystalline structure along their entire length (more than tens of micrometers) and further confirms that the obtained nanotubes are entirely hollow. The contrast clearly shows uniform hollow core of about 20 nm and uniform wall thickness of about 5 nm, which are equal to the Ge cores template and Si shell regions respectively, of the core-shell nanowire structure. The interference fringes obtained for a typical nanotube (3.14 nm) is in agreement with the interplanar distance of silicon with a cubic structure, in contrast to the measured spacing of the crystallographic planes in core-shell nanowires (see, FIG. 1C), which matched to the interplanar of Ge. This observation, detected in all of the silicon nanotubes prepared, indicates that the nanotubes are relaxed to their equilibrium lattice spacing after the etching process. The upper inset of FIG. 1D presents the corresponding two dimensional Fourier transform (2DFT) of the lattice-resolved image and shows that it can be indexed to the diamond structure of silicon with a [111] growth direction. The bottom inset of FIG. 1D presents a HRTEM image of the high quality crystalline wall of the corresponding Si nanotube on a scale bar of 5 nm.

Further confirmation of the crystalline structure of the formed nanotube was carried out by EDX analysis. FIG. 1H presents representative EDX spectra, on a scale bar of 50 nm, recorded along the longitudinal axis of a representative Si nanotube at different sites. The colored circles highlight the representative measured sites, which reveal a well correlated Si signal and a small residue of Ge (1-2%). Similar spectra were obtained for all the hollow nanostructures obtained, and revealed a very small residue of Ge, less than 1%, if any, and a well correlated Si signal along the longitudinal axis of the nanotubes.

These results manifest successful preparation of the silicon nanotubes.

Since the diameter of the Au eutectic liquid droplet is the primary factor in controlling the nanowire diameter for VLS growth, and thus the resultant nanotubes inner diameter, nanotubes with variant inner diameters were prepared by changing the size of the Au nanocluster.

FIG. 1E shows a set of representative HRTEM micrographs of single-crystalline Si nanotubes with different inner diameters, formed by utilizing Au nanoclusters giving a size of about 5 nm (left image), about 10 nm (middle image) and about 20 nm (right image). The contrast clearly shows hollow cores of about 5 nm, about 10 nm and about 20 nm, respectively, which are nearly the same as the initial size of the Au nanoclusters. As shown in FIG. 1E, these nanotubes are straight, smooth, with uniform diameter and uniform wall thickness of about 5 nm along their longitudinal axis, and exhibit high crystallinity The lattice spacing obtained for each typical nanotube, is in agreement with the interplanar distance of silicon with a diamond-like crystal structure.

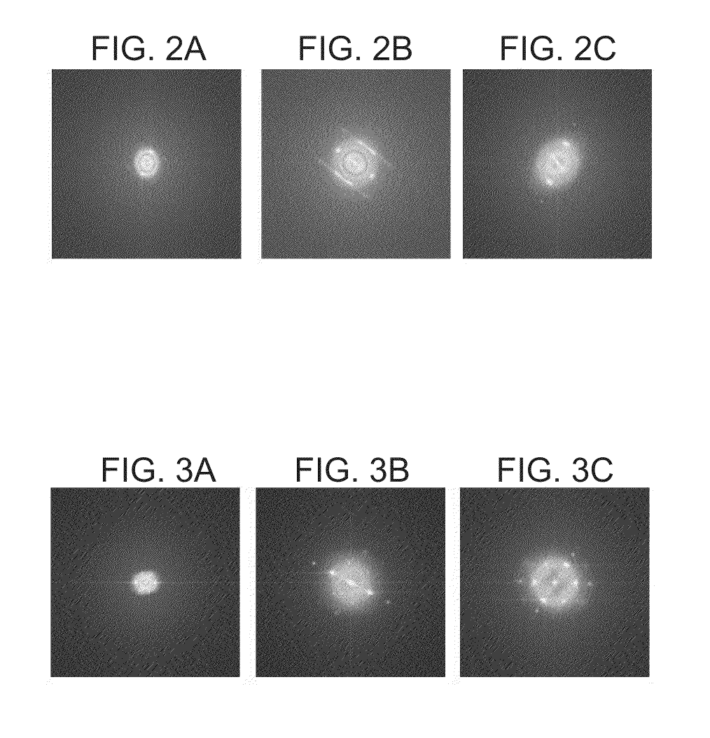

FIGS. 2A-C present Fast Fourier transform (FFT) images of a single-crystalline Si nanotubes with uniform inner diameter of about 5 nm (FIG. 2A), about 10 nm (FIG. 2B), and about 20 nm (FIG. 2C), and further confirms a uniform diamond crystal structure of Si obtained in all samples.

The wall thickness of the nanotubes can also be rationally controlled by adjusting the deposition time of the Si shell, during the nanowire growth process. The wall thickness variation at three different shell deposition times was studied. FIG. 1F presents a series of HRTEM images of single-crystalline Si nanotubes which confirms variation of wall thickness as a function of the shell deposition time. Thus, FIG. 1F presents a series of HRTEM images of single-crystalline Si nanotubes having a uniform wall thickness of about 5 nm (left image), about 10 nm (middle image) and about 20 nm (right image), which correspond to 20, 40 and 120 minutes shell deposition time, respectively. Furthermore, FIG. 1G presents a plot of the shell thickness as a function of shell deposition time, and clearly shows a positive correlation between the two parameters.

FIGS. 3A-3C present the FFTs corresponding to the HRTEM images presented in FIG. 1F, and further confirm that the obtained nanotubes have a cubic diamond crystal structure of Si.

### Example 2

### Nanostructures with Controllable Inner Diameter

### Synthesis and Structural Characterization of Si Single-Walled Nanotubes Having Ultra-Small or Ultra-Large Diameters

Using the methodology described herein for forming Si nanotubes, further optimization and control of the core-template diameter, so as to obtain Si nanotubes with ultra-small and ultra-large inner diameter, can be effected. Accordingly, Si nanotubes with ultra-small inner diameter of down to about 1.5 nm, have been successfully synthesized. Si nanotubes having ultra-large diameters of 100 nm and about 400 nm, which are ideally suited for e.g., nanofluidic applications, have been also successfully synthesized.

As demonstrated hereinabove, controlling the Ge-template diameter can be effected, to some extent, by manipulating the size of the Au nanoclusters. Such a methodology, however, is limited to a certain size range of the gold nanoclusters. It has been previously reported that germanium VLS growth of nanowires from large gold seeds particles (d≧50 nm) may in some cases produce Ge nanowires in low yields at low growth temperature or to overproduce nanowires at high temperatures, due to splitting of the gold seeds [Hong et al. 2005, Angew. Chem. Int. Ed. 44, 2-5]. On the other hand, small gold seeds (d≦5 nm) may in some cases lead to nanowires growth with a diameter that is larger than that of the initial particles, as a result of a combination of axial and radial growth.

In order to produce Si nanotubes having ultra-small diameter (smaller than 5 nm) or ultra-large diameter (larger than 100 nm), the following strategies were designed and successfully employed:

Si Nanotubes with Ultra-Large Inner Diameters:

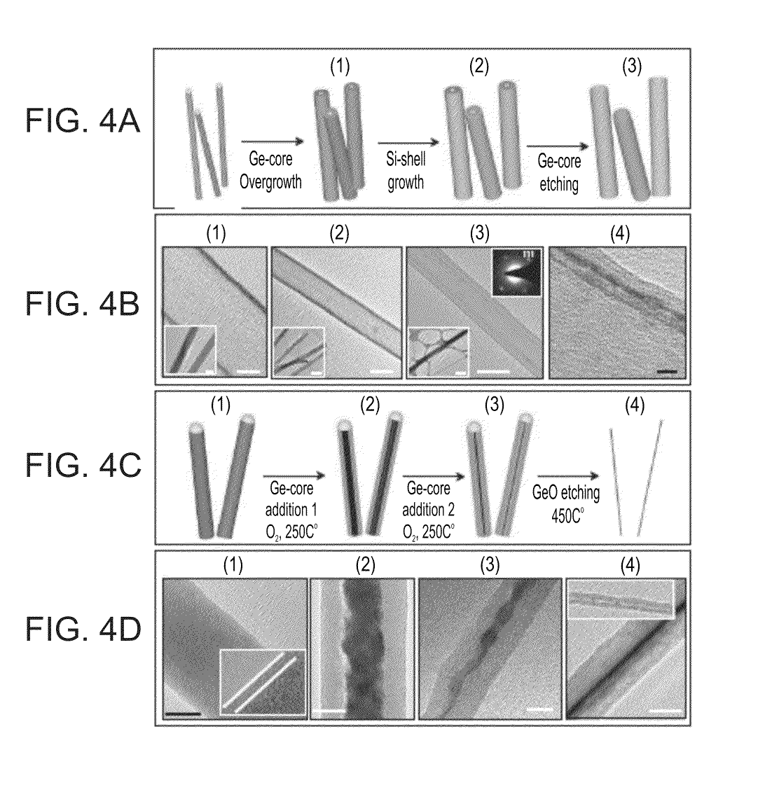

The first strategy involves enlargement of the Ge-core and results in fabrication of nanotubes with ultra-large inner diameters, as schematically illustrated in FIG. 4A. As can be seen in FIG. 4A, this strategy includes an additional step which is a core-enlargement process. This process involves conformal deposition of a Ge shell on top of the original Ge core (having a diameter of about 20 nm) (1). The growth of the Ge-shell is carried out at a higher temperature of 360° C., so as to promote a radial growth. By varying the deposition time of the Ge-shell, it is feasible to enlarge dramatically the original core size, while keeping intact the crystallinity of the Ge core. Thereafter, epitaxial deposition of Si shell on top of the ‘broadened’ Ge nanowires is performed (2), followed by selective removal of the entire (enlarged) Ge core, to thereby form crystalline Si nanotubes with larger inner diameters (3).

In an exemplary procedure, Ge nanowires were grown at 280° C., using 10% germane in 200 sccm H₂ and 400 Torr (axial growth). Ge shells were then deposited at 360° C., at 4 Torr (radial growth), using 5 sccm Germanium (10% in H₂) and 200 sccm H₂], at different deposition times. Si shell was thereafter deposited onto the Ge shell, as described hereinabove, followed by detachment from the substrate and selective removal of the entire Ge template, by dispersion in pentanol and a selective etching by H₂O₂, as described hereinabove, to thereby obtain Si nanotubes with enlarged inner diameter.

The obtained Si nanotubes, having ultra-large inner diameter, were structurally characterized.

FIG. 4B presents low resolution TEM images of nanotubes prepared as described hereinabove, in Ge-shell deposition times of 2, 4, and 10 minutes, and having a uniform inner diameter of 60 nm (FIG. 4B image 1), 100 nm (FIG. 4B image 2) and about 400 nm (FIG. 4B image 3), respectively, along their longitudinal axis, and a uniform contrast, which are indicative of single crystalline structures, and length of tens of microns. The aforementioned diameters are consistent with the diameter of the Ge core templates, after the enlargement process (as shown in the lower insets of FIG. 4B). In all cases, the enlargement process was performed on the original 20 nm Ge nanowires. A HRTEM image of a representative Si nanotube, prepared using this methodology is presented in FIG. 4B, image 4, and indicates that the nanotubes are single-crystalline with the same crystal orientation along the entire nanotube and with uniform and smooth wall thickness of about 5 nm. Furthermore, a selected area electron diffraction (SAED) pattern (see, upper inset of FIG. 4B, image 3), taken from a representative Si nanotube, confirms that the resultant nanotubes have a diamond cubic structure of Si with [111] growth direction.

Si Nanotubes with Ultra-Small Inner Diameters:

The strategy for fabricating Si nanotubes with ultra-small inner diameter involves post-growth core thermal oxidation process. Using this approach, nanotubes with an inner diameter of less than 1.5 nm have been prepared. FIG. 4C presents a schematic illustration of all the major steps for obtaining Ge-core template with a reduced inner diameter. As shown in FIG. 4C, a thermal oxidation of the formed Ge nanowires (1) is performed by first vaporizing the native oxide sheath (GeO₂) at 450° C., followed by flowing oxygen at 1 Torr and 250° C. at different oxidation times, in the range of 1-3 hours (2) and (3). Vaporization of the native oxide sheath (GeO₂) of about 1 nm (dashed lines in the inset of FIG. 4D (1)) at 450° C. is essential for performing the following thermal oxidation of the Ge core. The systematic variation of the thermal oxidation time in the range of 1-3 hours, at 250° C. and 1 Torr O₂, enables to reproducibly control and dramatically reduce the diameter of Ge-nanowire templates obtained by the conventional synthetic procedure. Thereafter, the formed GeO is etched at 450° C. (4), by flowing oxygen at 1 Torr.

FIG. 4D presents low resolution TEM images of Ge nanowires before (FIG. 4D (1)) and after (FIG. 4D (2), (3), (4)) the thermal oxidation process, which clearly show the distinct boundary between the amorphous germanium oxide layer (light region) and the Ge core (dark region), and the dramatic reduction in the core diameter, from 20 nm, the original core template (FIG. 4D (1)) to about 10 nm (FIG. 4D (2)), to about 4 nm (FIG. 4D (3)) and to about 1.5 nm (FIG. 4D (4)), alongside the monotonous increase of the oxide sheath.

Vaporization and removal of the oxide layer at 450° C., followed by growth of a conformal Si shell and selective removal of the Ge-core, lead to the formation of nanotubes with significantly smaller inner diameter with respect to the initial core-template. The inset of FIG. 4D (4) presents a representative Si nanotube with a diameter of only about 1.5 nm, formed via the thermal oxidation treatment, demonstrating the capability to synthesize nanotubular structures with ultra small-inner diameter of less than 1.5 nm.

Thus, by utilizing the methodologies presented hereinabove, nanotubes of nearly any size can be prepared. This level of control allows tailoring the tube size to fit the desired application.

### Example 3

### Chemically Modified Nanostructures

### Synthesis and Structure Characterization of Single-Walled Single Crystalline SiₓGe₁₋ₓ Alloy Nanotubes and p-Type Si Nanotubes

The chemical composition of the silicon nanotubes prepared using the methodologies described herein can further be rationally and precisely controlled. By subsequent introduction of dopants and other reactants, nanotubes with variant composition can be formed.

Thus, single-crystalline SiₓGe₁₋ₓ alloy nanotubes were synthesized based on the template approach, using germane (GeH₄), which was fed into the CVD system simultaneously with silane (SiH₄) during the shell growth step, and was incorporated in an individual nanowire-template. In an exemplary procedure, alloy silicon shells were deposited on Ge-nanowires prepared as described hereinabove, using silane (0.5 sccm) and 50 sccm of 10% germane in 200 sccm H₂ at 1 Torr.

The formed SiₓGe₁₋ₓ alloy nanotubes were identified as Si_{0.94}:Ge_{0.06} alloy by EDX-occupied TEM, using a k factor of Si K_{α} and Ge K_{α} radiation in the EDX spectra (data not shown). The obtained Si:Ge composition was variant only within 0.5% variation along the nanotube, suggesting appropriate alloying of Si and Ge within the nanotubes.

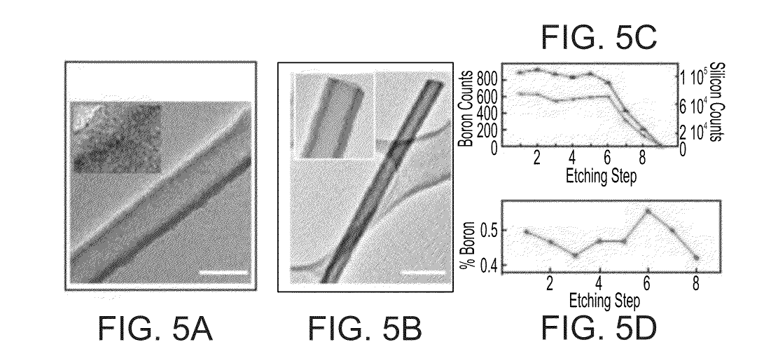

FIG. 5A presents a low resolution TEM image, on a scale bar of 50 nm, of a representative Si_{0.94}:Ge_{0.06} alloy nanotube with uniform inner diameter of 20 nm, formed by subsequent introduction of GeH₄ during the shell growth process. A HRTEM of the nanotube edge (inset) shows a high-quality single-crystalline structure, with the same crystal orientation along the entire nanotube length. The observed lattice spacing (0.318 nm) corresponds to the d-spacing of the (111) crystal planes of Si with a cubic structure and [111] growth direction.

SiₓGe₁₋ₓ alloy nanotubes of different Si/Ge compositional ratio can be obtained using the above-described methodology, preferably at Ge concentrations lower than 60%. At such Ge concentrations, the obtained nanotube walls are stable in the H₂O₂ etching solution, while higher Ge percentages may lead to nanotube walls that are unstable during the etching step of the Ge core. The presence of Si in the alloy, at concentrations higher than 40%, inhibits the etching of the SiGe alloy [see, Bircumshaw et al. 2004, Technical Digest, IEEE, 17th International Conference on Micro Electro Mechanical Systems, p. 514]. Also contemplated are other types of Si—Ge compositions.

In another methodology, single-crystalline p-type Si nanotubes were synthesized based on the template approach, using diborane (B₂H₆), which was fed into the CVD system simultaneously with silane (SiH₄) during the shell growth step, and was incorporated in an individual nanowire-template. In an exemplary procedure, p-type silicon shells were formed by incorporation of diborane (5 sccm) and silane (5 sccm) at 1 Torr.

The relative boron composition in the p-type Si nanotubes was quantitatively determined, using Time-Of-Flight Secondary Ion Mass Spectroscopy (TOF-SIMS) analysis combined with sputtering process. FIGS. 5C and 5D present plots showing a compositional depth profile which was carried on the p-type Si nanotubes prepared, and demonstrating that the B/Si ratio which was measured sequentially after multiple etching of the nanotubes was about 1/200 atomic ratio.

FIG. 5B presents a representative low resolution TEM image of an in-situ p-type doped Si nanotube, which was formed by subsequent introduction of diborane during the Si shell growth, on a scale bar of 200 nm. The inset shows a large magnification of the opened end of the nanotube.

The subsequent introduction of diborane during the Si shell growth step was observed to influence the wall thickness of the obtained nanotubes. As shown in FIG. 5B, the nanotubes possess wall thickness of about 20 nm, compared with wall thickness of about 10 nm obtained for pristine Si nanotubes (see, FIG. 1F, middle image) in an identical shell growth duration of 40 minutes.

These results indicate that by changing the reactant partial pressure, p/n type Si nanotubes and SiₓGe₁₋ₓ nanotubes can be formed with different doping density and Si to Ge ratio, respectively. This ability to encode the system creates the possibility to tune the electrical/optical characteristics of the formed nanotubes to better-suit various applications.

### Example 4

### Nanotubular Structures with Controllable Shape

### Synthesis and Structural Characterization of Conical and Funnel-Like Si Single-Walled Nanotubular Structures

The shape of semiconductors at the nanoscale is an essential factor for their properties, and thus the shape-controlled growth of semiconductors can find applications in electronics and photonics.

The fabrication of Si nanostructures having the shape of ‘hollow cones’ was designed and successfully practiced.

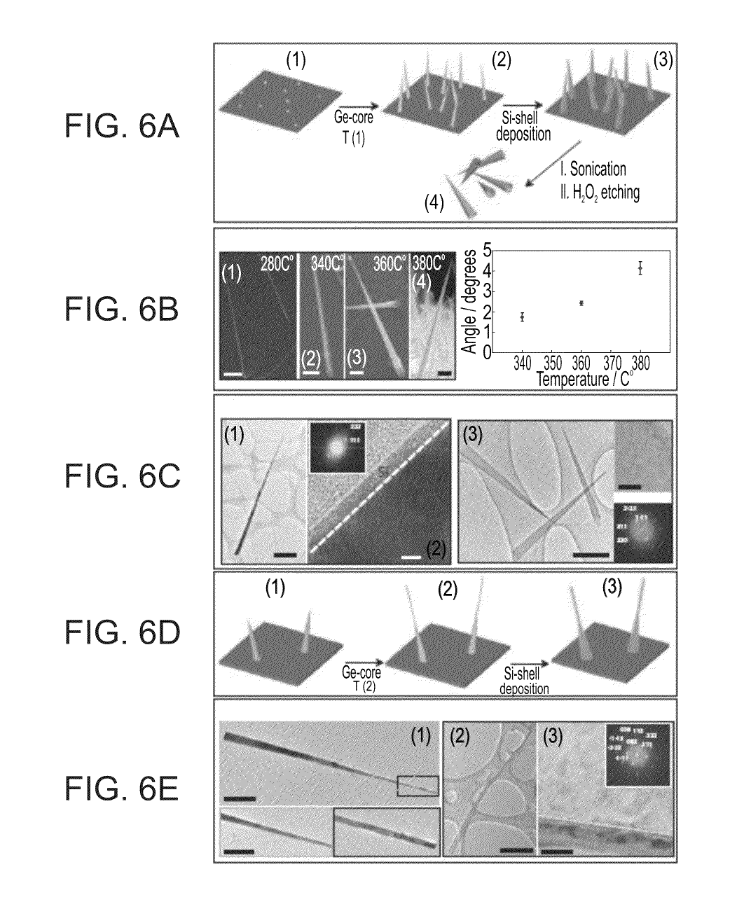

FIG. 6A schematically illustrates the experimental procedure used to fabricate conical Si nanotubular structures. The procedure is similar to that described in Example 1 for producing Si nanotubes, except that the formation of the nanowire-templates is carried out at a higher temperature, in order to produce a cone-like shape as a result of axial and conformal growth. Thus, Au nanoparticles of 20 nm in diameter are deposited on a substrate (1), growth of Ge-cone nanowire at various substrate temperatures is thereafter effected (2), followed by epitaxial coating with Si shell at 450° C. (3), and dispersion into pentanol and chemical etching with H₂O₂ at 60° C. for 2 hours, to thereby form Si conical nanotubular structure (4).

In order to form conical nanotubular structures with different taper angles, a series of nanowires-template growths at substrate temperatures of 340° C., 360° C. and 380° C. was performed, using 200 sccm H₂ and 30 sccm germane at 100 Torr.

FIG. 6B (1-4) presents a series of scanning electron microscopy (SEM) images of Ge nanostructures whose shape was controllably tuned from nanowires to nanocones, by growing the nanowires at 280° C., 340° C. 360° C. and 380° C., respectively, thereby producing nanocones with various tapering angles. As shown in FIG. 6B, the shape varies from a wire shape at 280° C., with a uniform diameter of 20 nm along the entire length (image (1)), to conical shaped with various taper angles ranging from 1.8° at 340° C., through 2.5° at 360° C., and to 4.2° at 380° C. (images (2), (3) and (4), respectively). A plot of the taper angle as a function of the growth temperature is depicted in FIG. 6B (5) and clearly shows a positive correlation between the two parameters. The taper angle is dependent on the growth temperature, and increased by a factor of 2 with increasing the temperature from 340° C. to 380° C. The plot was constructed based on the statistical distributions of taper angle measured over 10 Ge cone nanowires at each growth condition of temperature (340° C., 360° C. and 380° C.).

The conical nanowires which were grown at 380° C. were coated with a 5 nm thick Si shell. Both low and high resolution TEMs were used to characterize the shape, shell thickness, and crystallinity of the obtained cone nanowires. FIG. 6C (1) shows a representative low resolution TEM image of Ge nanowire with a cone-like shape that was grown at 360° C. FIG. 6C (2) presents a HRTEM image of the cone edge of a typical Ge—Si core-shell conical nanowire and demonstrates a high quality single-crystalline core-shell structure with epitaxial growth of the Si shell along the entire length. It is shown that Ge-core (dark) and Si-shell (bright) grow with a diamond crystal structure of Ge and along [111] growth direction. The lattice spacing of both the shell and the core (0.33 nm) corresponds to the d-spacing of (111) crystal planes of Ge with cubic structures. This observation was confirmed by the FFT of the TEM image (inset of FIG. 6C (2)).

Selective extraction of the Ge core from the core-shell nanocones resulted in the formation of the desired hollow Si nanocones, with uniform sheath and smooth surface, as shown in the low resolution TEM image presented in FIG. 6C (3). The nanotubular structure is complementary to the morphology of the Ge template, with the interior void determined by the dimension of the core template, which was grown at 380° C. A lattice-resolved image of a typical conical nanotube (upper right inset) and its FFT image (lower right inset) indicated that the resultant nanotubes have a cubic diamond crystal structure of Si with [111] growth direction.

The above results indicate that the methodology described herein enables a further degree of controllability of the Si nanostructures shape and taper angle by controlling the growth variables.

In addition to a nanocone shape, funnel-like nanotubular Si structures were also successfully produced. FIG. 6D schematically outlines the major steps used to form ‘funnel’-like nanotubular structures. Since a funnel-like shape consists of two types of nanostructures: cone and wire, in this procedure, the fabrication of the Ge-template involves two steps, each referring to the formation of each nanostructures. The procedure includes Ge cones growth at temperature of 360° C. (1), and then, under continued flow of GeH₄, the temperature was gradually lowered to 280° C. to initiate the growth of the wire (2) and then maintained at 280° C. to continue the growth of the wire.

The formed ‘funnel’-like nanowire was then coated with a Si shell, to give Ge—Si core-shell ‘funnel’-like nanostructure (3).

FIG. 6E(1) presents a low resolution TEM image of a representative funnel-like nanowire template (upper image), and magnifications of the marked junction point between the cone and the wire (yellow rectangular, lower image), and the region of the wire growth therefrom (black rectangular, lower image).

The ‘funnel’-like nanowire-templates were then transformed into nanotubular structures with uniform, high crystalline sheath and smooth surface. FIG. 6E (2) presents a low resolution TEM image of a representative ‘funnel“-like hybrid nanostructure and demonstrates that the obtained nanostructures possessed complementary morphology to that of the Ge template that grew at 340° C. FIG. 6E (3) presents a high resolution TEM image and its FFT (inset), which verify that the resulting nanotubular structures are high quality single-crystalline Si nanostructures and that the reciprocal lattice peaks obtained from the FFT can be indexed to the cubic structure of Si, with [111] growth direction.

These results further demonstrate the reproducible, systematic variation in the shape of the Si nanostructures formed as described herein, which enables to controllably tune not only the diameter, wall thickness and composition but also the geometry of the Si nanostructures, from wire-shape to conical and ‘funnel’ shape, where all the structures are single-crystalline.

### Example 5

### Surface-Modified Nanostructures

### Fine Tuning of the Solubility Characteristics of Si Single-Walled Nanotubes Using Chemical Modification techniques

Pristine Si nanotubes are insoluble in most solvents and tend to form aggregates. Therefore, the functionalization of the fabricated Si nanotubes with various hydrophilic or hydrophobic chemical groups can be used to render the produced nanotubes suitable for applications such as separations (selective filtering), selective transport and sensing of chemical and biological molecules.

The solubility of Si nanotubes was modified by the covalent bonding of silane molecules with different functional groups onto the outer surface thereof.

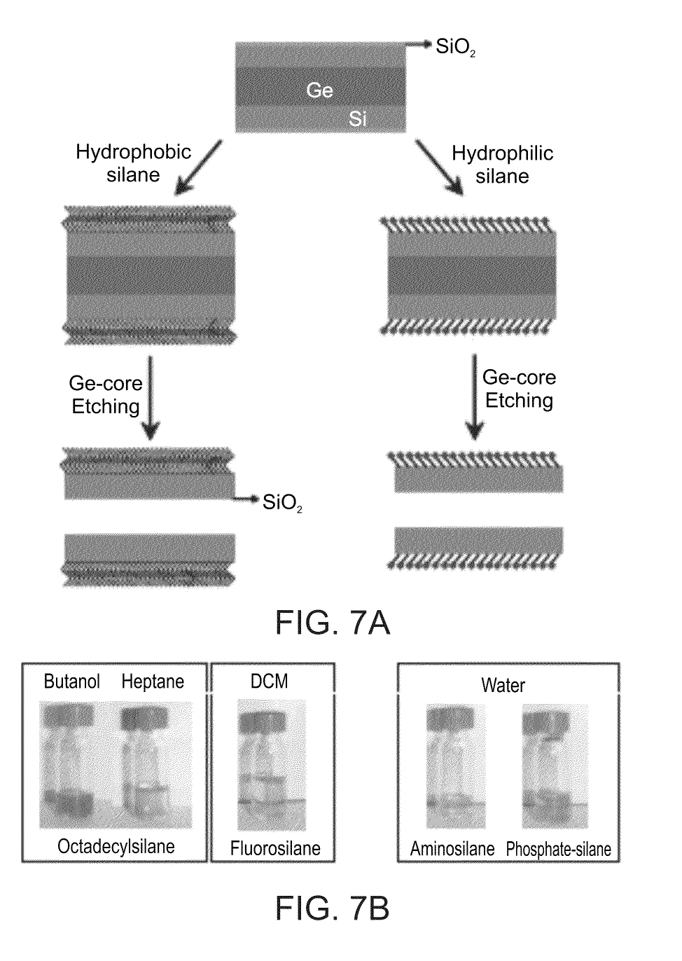

FIG. 7A schematically describes an exemplary functionalization procedure, used for enabling dispersion of the Si nanotubes in various solvents.

All the modifications are carried out on the core-shell nanowires surface. This allows modification of the external surface of the subsequent nanotubes without affecting their inner surface. The outer surface of the Si-coated nanowires terminates in silanol, SiOH, groups which are employed as anchoring sites for silane molecules to form Si—O—Si covalent bonds.

A general procedure for functionalization of the Si nanotubes is carried out on the Ge—Si core-shell nanowires surface by incubation of the growth substrate in a solution of different silane derivatives with different polarity (i.e. either hydrophobic silane or hydrophilic silane), for about 2 hours, so as to effect a direct attachment of the silane derivatives to the silicon shell of the nanowires-template.

The functionalized nanowire substrate is then rinsed with appropriate solvents (e.g., butanol, heptane, dichloromethane and water, depending on the nanowires surface modification performed), followed by curing at 110° C. in an oven for 10 minutes. The functionalized Si-coated nanowires are thereafter removed by sonication from the SiO₂ substrate, followed by further etching of the core material, with H₂O₂ at 60° C. for 2 hours. Then, the fuctionalized Si nanotubes are centrifuged and washed, resulting in nanotubes having either a hydrophobic or hydrophilic exterior, depending on the nature of modification. The interior of the thus obtained nanotubes is left unfunctionalized during this process and hence the nanotubes possess a hydrophilic void. Further modification of the hydrophilic interior can be readily performed.

Using the above general procedure, various functionalized Si nanotubes were prepared and dispersed into various liquid suspensions (common organic solvents and water).

In exemplary procedures, the substrate-bound Ge—Si core/shell nanowires were embedded in the following solutions: 1% aminosilane in water; 5% phosphate-silane in water, 2% fluorosilane in dichloromethane (CH₂Cl₂) and 2% octadecysilane in dichloromethane. The samples were then rinsed with appropriate solvent, and cured at 110° C., for 10 minutes, in an oven. After sonication and an etching process, the resulting functionalized Si nanotubes were centrifuged, washed and dispersed into various liquid suspensions (organic solvents and water).

FIG. 7B illustrates representative results of the functionalized Si nanotubes dispersions. Covalently linking of aminosilane and phosphate-silane to Si nanotubes surface resulted in Si nanotubes readily soluble in water (see, FIG. 7B, right image). Organic-soluble Si nanotubes were obtained by functionalization with fluorosilane (FIG. 7B, middle image) and octadecylsilane (FIG. 7B, left image).

### Example 6

### Fabrication of FET Devices from p-Doped Single-Walled Si Nanotubes

The nanostructures described herein can be integrated into electrical devices useful for many applications.

As an example, field effect transistor (FET) devices were fabricated from p-doped Si nanotubes as described herein, and electrical transport measurements were carried out to evaluate the device performance. The electrical properties of the nanotubes are indicative of their suitability for electrical applications.

A liquid suspension of p-doped Si nanotubes having an inner diameter of 20 nm and a wall thickness of 4 nm, prepared as described in Example 3 hereinabove, was dispersed on a highly doped Si substrate with a 600 nm thick silicon oxide (SiO₂) dielectric layer, followed by the formation of Ni/Au source drain electrodes/contacts which were carried out by e-beam lithography.

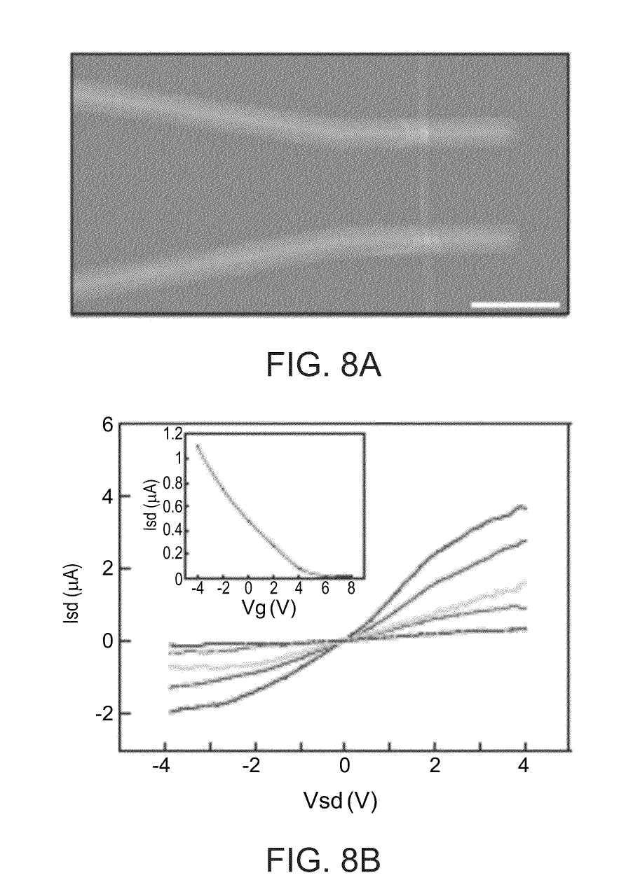

FIG. 8A shows an HRSEM image of a typical FET device consisting of an individual Si-nanotube with source-drain contacts (typical separation of 1 μm).

Next, an annealing step was carried out by rapid thermal annealing (RTP) to form a stable conducting silicide with a low schottky barrier on p-type silicon. The highly doped Si substrate serves as the back-gate.

The transport characteristics of the thus formed device were studied.

FIG. 8B shows the current (I_{sd}) versus drain-source bias (V_{sd}) (output characteristics) of individual p-type Si nanotube field effect transistors at various gate voltages (V_{g}). The current recorded on the boron-doped Si nanotube is plotted against various gate voltages (V_{g}) of: −4V (pink), −2V (green), 0 V (yellow), +2V (red) and −4 V (blue) (FIG. 8B).

As can be seen in FIG. 8B, the gate voltage dependence is a typical character of p-type FET-behavior [see, for example, Cui et al. 2001, Science 293:1289-1292; Lauhon et al. 2002, Nature 420: 57-61; and Kim et al. 2007, Appl. Phys. Lett. 91: 033104-1-033104-3]. Consistent with this behavior is the current variation as a function of the applied gate voltage (I_{sd}-V_{g}) at constant V_{sd} of +1 V (see the inset of FIG. 8B).

### Example 7

### Synthesis of NiSi/Si Multi-Segment Single-Walled Nanotube Heterostructures

Metal/semiconductor nanotube heterostructures are obtained, for example, by transforming the pristine single-crystalline nanotubes prepared as described herein to NiSi/Si multi-segment nanotube heterostructures. These periodic “gating segments” along the axis of the nanotubular channel are lithographically defined, and are coated with nickel. After lift off step, annealing process is carried out via rapid thermal annealer (RTP) at different temperatures and time to form semiconductor gaps with length down to a few nanometers.

### Example 8

### Synthesis and Structural Characterization of Double-Walled Tubular Nanostructures

The methodology described in previous examples for forming Si single-walled nanotubes is further extended herein so as to produce silicon multi-walled, namely, tube-in-tube and wire-in-tube, nanostructures.

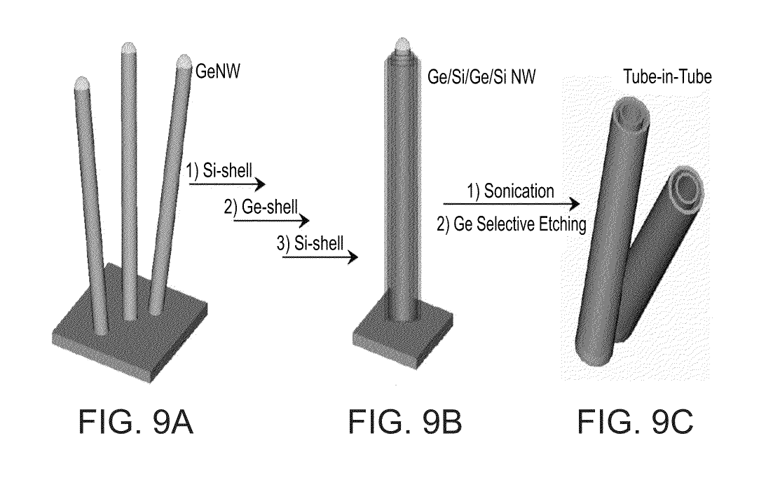

FIG. 9 presents a schematic illustration of a process of preparing Si multi-walled (tube-in-tube) nanostructures according to some embodiments of the invention.

The growths were carried out with the use of Si (100) substrates with deposited gold nanoparticle catalysts (AuNPs). The Ge(core)-Si—Ge (multishell) heterostructured nanowires are synthesized with germane (GeH₄) as a gas source to form the germanium cores, and silane (SiH₄) and GeH₄ (and dopants or additional materials when required) as the source gases for the deposition of silicon and germanium shells, on the initially formed germanium core, by switching the gas source during the growth.

As shown in FIG. 9A, growth of intrinsic germanium nanowires from (e.g., 20 nm) gold nanoparticles which are initially deposited on the silicon wafer as catalysts, is first effected. As shown in FIG. 9B, growth of conformal shells, by alteration of the experimental conditions to favor conformal homogeneous vapor-phase deposition on the nanowires is then effected. A subsequent introduction of SiH₄ and GeH₄ produces multiple shells: a silicon shell which grows directly on the nanowire surface followed by deposition of a germanium shell as a second layer, and then again a silicon shell as a third layer. The thickness of each shell can be readily controlled by varying the deposition time. As shown in FIG. 9C, transformation of the resulting core-multishells nanowire heterostructures to tube-in-tube nanostructures by the selective chemical etching of the germanium sacrificial interlayers is then effected.

As shown in FIG. 9, single crystalline germanium nanowires are first prepared as described hereinabove (see, for example, Example 1).

Accordingly, Au nanoclusters with a desired diameter, such as, for instance, of 20 nm, are deposited on a Si (100) substrate, from a colloidal solution. As noted in previous examples, the diameter of the gold nanoparticles defines the diameter of the Ge core, and, in this exemplary procedure, it specifies the resultant diameter of the inner silicon nanotube.

The growth substrate is thereafter placed in a chemical vapor deposition system (CVD), as described hereinabove. The first CVD step involved the formation of the Ge core template using germane (GeH₄) as a precursor and H₂ as a carrier gas. Thus, for example, in the first CVD step, a mixture of 10% germane (GeH₄) in 200 sccm H₂ is processed at 280° C. and 400 Torr, for forming the Ge core template. Thereafter, in the second CVD step, silane (5 sccm SiH₄) in a mixture of 10 sccm H₂ and 5 sccm Ar as a gas carrier is introduced to the CVD and processed at 1 Torr, and at an increased temperature of 450° C. Si deposition is performed in varying deposition times, leading to the conformal and epitaxial deposition of a Si shell on top of the Ge core template.

As further described herein (see, Example 3), introduction of dopants and other reactants to the silicon coating can be effected, so as to impart the nanotubes variable properties, if desired. The above process can therefore further involve the formation of multi-walled nanotubes with variant composition, in some of all of the formed nanotubes in the multi-walled nanostructures. For example, p-type/n-type silicon shells are prepared by feeding the CVD system simultaneously with 5 sccm diborane and 5 sccm phosphine, and 5 sccm silane (SiH₄) during the shell growth step and are to be processed at 1 Torr.

In subsequent CVD steps, deposition of germanium shells on top of silicon shells and deposition of silicon shells on top of germanium shells are effected repeatedly and interchangeably, as desired, to allow conformal homogeneous vapor-phase deposition and the formation of a multi-shell structure (FIG. 9B). The deposition of germanium shells is performed, for example, with a mixture of 10% germane (GeH₄) in 200 sccm H₂ at a reduced temperature of 330° C. and 100 Torr for different periods of time, depending on the desired distance between the silicon tubes in the multi-walled structure. Since the obtained Ge shells were found to possess poorly crystalline or even amorphous structure, the Ge shells are crystallized by a series of annealing procedures. In order to prevent degradation of the conformal smooth germanium shells, the annealing procedures are carried out at temperature of from 330° C. to 450° C.

The deposition of silicon shells is carried out as described hereinabove (see, for example, Example 1).

Once the sequential deposition of Ge and Si shells in completed, the resulting substrate-bound multi-shells nanowire heterostructures are sonicated in pentanol in order to separate them from the growth substrate.

In the final step, selective chemical etching of the germanium sacrificial interlayers is used for transforming the resulting core-multishells nanowire heterostructures into tube-in-tube multi-walled tubular nanostructures (FIG. 9C).

The etching of the inner Ge-nanowire template and of the Ge shells is carried out, for example, in a solution of 1:3 v/v hydrogen peroxide (H₂O₂):pentanol at 60° C. for about 2-3 hours.

FIG. 9C illustrates a silicon tube-in-tube structure (double-walled silicon nanotube-like (DWSiNTs-like) structure) which is produced by (1) dispersing the core(Ge)-shell(Si)-shell(Ge)-shell(Si) nanowires into pentanol and (2) selective etching of the Ge by H₂O₂ at 65° C.

The prepared single-crystalline multi-walled nanostructures are then centrifuged, washed several times with ethanol, and then deposited on top of either copper grids or lacey copper grids for TEM measurements, and other structural characterization, as detailed hereinbelow.

Structural Characterization:

Without being bound by any particular theory, a proposed mechanism involved in the growth of germanium shells on top of silicon NW/shell is first discussed herein.

The growth of germanium films on top of silicon substrates has been studies before, and was found to be a complex problem involving different factors such as growth direction, surface faceting, germane (GeH₄) partial pressure, deposition temperature etc. The lattice mismatch between germanium and silicon, being about 4.2%, places strict limitations on achieving conformal, smooth germanium layers on silicon surfaces.

Generally, there are three modes of heteroepitaxial growth: Frank-van der Merwe (FvdM), Volmer-Weber (VW) and Stranski-Krastanow (SK), which can be loosely described as a layer-by-layer growth (2D), island growth (3D) and layer-by-layer plus islands growth, respectively. The heteroepitaxy of relaxed germanium films on silicon have attracted great interest due to many important applications in semiconductor technology. Reference is made to the following publications: Schäffler et al. Semicond. Sci. Technol. 12, 1515-1549 (1997); Halbwax et al. J. Appl. Phys. 97, 0649071-064907-6 (2005); Calarco et al. Thin Solid Films 391, 138-142 (2001); Eaglesham. & Cerullo, Phys. Rev. Lett. 64, 1943-1946 (1990); Mo et al. Phys. Rev. Lett., 65, 1020-1023 (1990); Jain & Willander, M. Silicon-Germanium Strained Layers and Heterostructures; Academic Press: San Diego (2003); Hanke et al. Appl. Phys. Lett. 84, 5228-5230 (2004); and Pan et al. Nano Lett. 5, 1081-1085 (2005).

The currently known methodologies for depositing germanium films on silicon substrates typically produce either layers that are several micrometers thick, which are not suitable for applications requiring lower thicknesses, or a transition from a layer-by-layer to island-based growth (as in the Stranski-Krastanow mode), which occurs at a “critical layer thickness”, and stems from a process of elastic relaxation.

Preliminary studies on the growth of germanium shells on silicon-nanowire cores were performed at relatively high deposition temperatures of 380° C. and 500° C. These experiments, however, were limited for a narrow range of core diameters and to certain shell thicknesses. In contrast, according to some embodiments of the present invention, uniform and conformally-smooth germanium shells are deposited on top of both core (Si) nanowires and core (Ge)-shell (Si) nanowires at a much lower deposition temperature of 330° C.

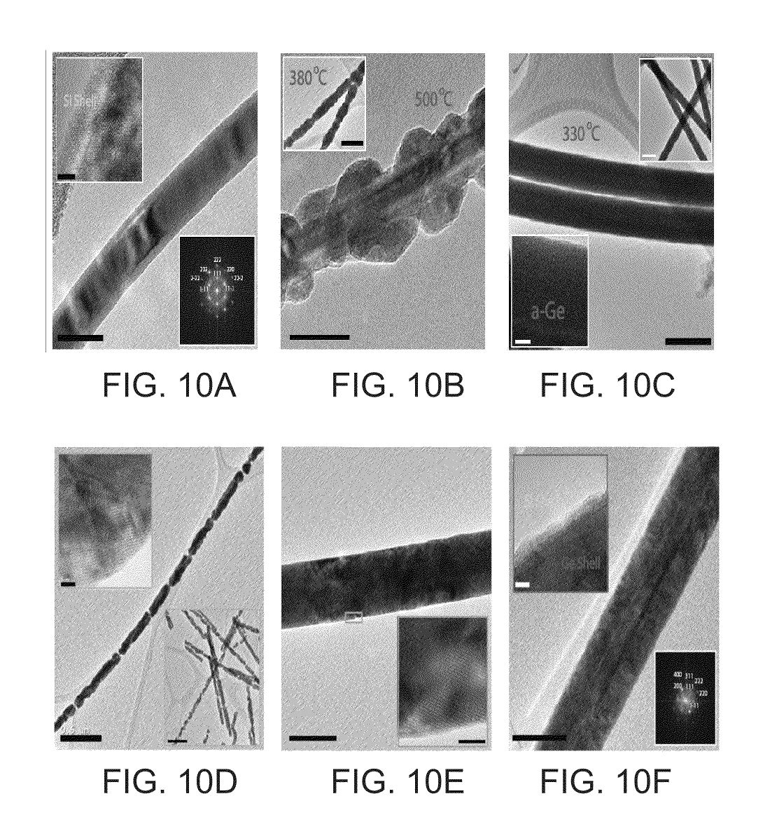

Characterization of the formed silicon multi-tube nanostructures was carried out as described hereinabove. Some of the data obtained are presented in FIGS. 10-13.

FIGS. 10A-F present the structural characterization of the nanowires obtained as intermediates en route the production of double-walled Si nanotubes.

FIG. 10A is a low resolution TEM (LRTEM) image of a Ge(dark)-Si(light) core-shell nanowire, recorded prior to the deposition of the germanium shell. The Ge—Si core-shell nanowire has a core diameter of 20 nm as defined by the diameter of the gold nanocluster used, and a silicon shell thickness of 5 nm, as determined by the deposition time. As shown in FIG. 10A, the core/shell interface is compositionally sharp. Top inset is a high resolution TEM (HRTEM) image, which shows a crystalline germanium core and a continuous, uniform crystalline silicon shell along the entire length of the nanowire heterostructure. Bottom inset is a fast Fourier transform (FFT) image of the corresponding sample shown in the top inset.

FIG. 10B is a LRTEM image of a core (Ge)-shell (Si)-shell (Ge) nanowires, wherein the deposition of the Ge shell is carried out at 500° C. The inset is a LRTEM image, of a core (Ge)-shell (Si)-shell (Ge) nanowire, wherein the deposition of the Ge shell is carried out at 380° C. It is shown that at a growth temperature of 500° C. the germanium is preferentially deposited on the surface of the core(Ge)-shell (Si) nanowires to form distinct 3-dimensional islands (or widely separated clusters). At a growth temperature of 380° C., the germanium is preferentially deposited on the surface of the core(Ge)-shell (Si) nanowires to form a relatively rough layer (3-5 nm roughness).

FIG. 10C is a LRTEM image, of a core (Ge)-shell (Si)-shell (Ge) nanowire wherein the deposition of the Ge shell of about 30 nm thick was carried out at 330° C. and 100 Torr. The upper inset is a LRTEM image, showing a uniform, smooth and amorphous Ge shell structure. The bottom inset is a HRTEM image, also showing uniform, smooth and amorphous Ge shell structure. As seen in the bottom inset, before an annealing procedure, there are no diffraction fringes observed in the germanium-shell structure. These data show that ultra low deposition temperature of the Ge shells leads to shells of relatively poor crystallinity. Accordingly, such deposition temperature enables the formation of smooth, unstrained conformal layers of germanium, without any constraints on either the thickness of the deposited shells or the initial core diameter.

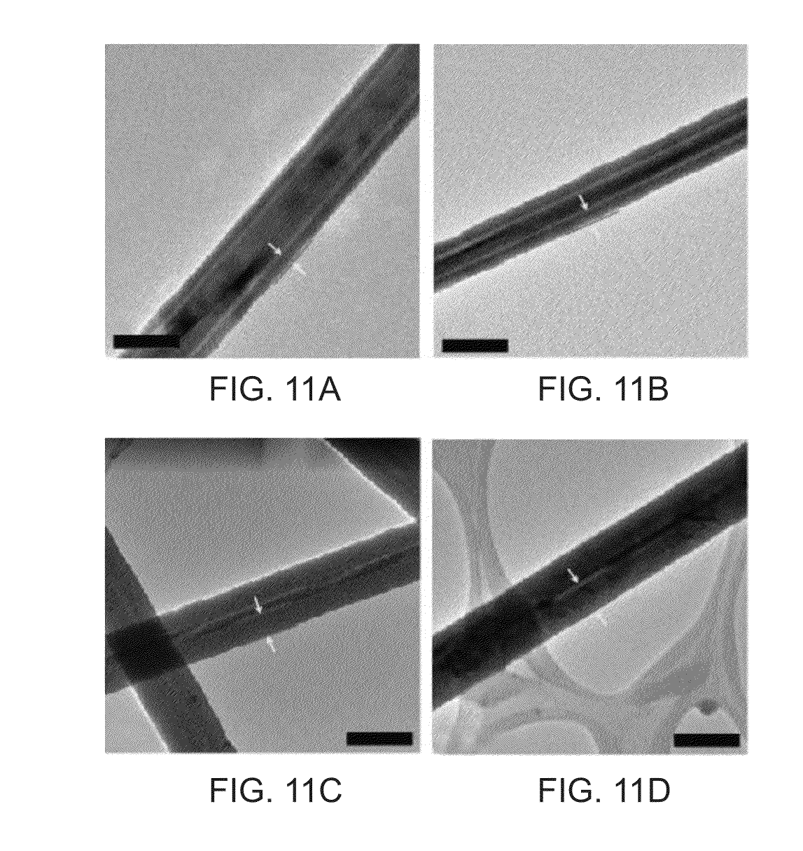

FIG. 11A-demonstrate that under the above-mentioned processing conditions (shown for FIG. 10C) it is feasible to form conformal germanium shells of variable thicknesses, ranging, for example, from 2 nm to up to 60 nm, regardless of the initial core diameter, by simply adjusting the shell-deposition time.

FIG. 11A is a LRTEM image of a core (Ge)-shell (Si)-shell (Ge) nanowire wherein the deposition of a 5 nm thickness Ge shell was performed at 330° C. and 100 Torr for 2 minutes.

FIG. 11B is a LRTEM image of a core (Ge)-shell (Si)-shell (Ge) nanowire wherein the deposition of a 10 nm thickness Ge shell was performed at 330° C. and 100 Torr for 4 minutes.

FIG. 11C is a LRTEM image of a core (Ge)-shell (Si)-shell (Ge) nanowire wherein the deposition of a 20 nm thickness Ge shell was performed at 330° C. and 100 Torr for 7 minutes.

FIG. 11D is a LRTEM image of a core (Ge)-shell (Si)-shell (Ge) nanowire wherein the deposition of a 30 nm thickness Ge shell was performed at 330° C. and 100 Torr for 10 minutes.

The impact of various annealing processes conducted at various temperatures and for various time durations on Ge shells was studies and showed that poorly-crystalline/amorphous germanium shell may be completely crystallized by means of an in-situ thermal-annealing step at 450° C.

The poorly crystalline/amorphous Ge shells obtained were crystallized by a pre-programmed stepwise heating protocol consisting of a series of temperature steps between 330° C.-450° C. (the temperature is increased by 10° C. steps, at a rate of 1° C./seconds, with waiting periods of 10 minutes at each step) in order to prevent degradation of the conformal smooth germanium shells, as shown in FIG. 10D.

FIG. 10D is a LRTEM image, of the nanowire shown in FIG. 10C, after subjecting it to annealing at a relatively fast heating rate of 10° C./second. The upper inset is a HRTEM image, of an island of the same nanowire, exhibiting a polycrystalline structure. The lower inset is a LRTEM image, of a plurality of nanowires obtained upon annealing.

It should be noted that the formation of periodic crystalline islands may indicate that dislocation loops are formed across the nanowire during the crystallization process [see, Raychaudhuri & Yua. J. Vac. Sci. Technol. B 24, 2053-2059 (2006)].

To further investigate the effect of the heating rate in the annealing step, the Ge shell which has been annealed at a relatively fast heating rate of 10° C./seconds was compared with a Ge shell which was formed via heteroepitaxial deposition of germanium on silicon shells, and have found that when the Ge shell has been annealed at a relatively fast heating rate, that crystallization begins at the Si/Ge interface, which after a certain “critical thickness” leads to the breaking of the strained germanium film into crystalline islands. A typical island with a polycrystalline structure is shown in FIG. 10D, top inset.

In case of a gradual heating rate higher than 10° C./10 minutes, fully crystalline germanium shells are obtained, without affecting the integrity of the initial germanium shell. FIG. 10E is a LRTEM image, of a nanowire shown in FIG. 10C after undergoing annealing with a gradual temperature increase (rate of 10° C./10 minutes), which shows that the annealed nanowire exhibits a smooth, uniform and crystalline Ge shell. The inset is a HRTEM image, of the obtained Ge shell, showing a highly-crystalline structure, and that a measured spacing of the crystallographic (111) planes matched well with the 0.32 nm interplanar distance of germanium with a diamond-like structure.

The next step involves the deposition of a second silicon shell.

A second Si shell was deposited at 450° C., as described hereinabove for the first Si shell. FIG. 10F is a LRTEM image, taken after the deposition of the second Si shell carried on top of the annealed nanowire shown in FIG. 10C. Top inset is a HRTEM image, revealing a crystalline Si shell. Bottom inset is a fast Fourier transform (FFT) image corresponding to the region shown in the top inset. As is clearly seen in FIG. 1-F, both Ge (dark) and Si (light) shells are continuous and uniform along the entire length of the nanowire. The resultant silicon shell grows epitaxially on the previous germanium shell and has a highly-crystalline structure, with lattice spacing of 0.20 nm, in excellent agreement with (220) planes of the diamond crystal structure of germanium.

Accordingly, this strain-relaxation mechanism was used to grow a series of germanium shells of different thicknesses, ranging from 2 nm to 60 nm (between 14 and 428 monolayers). See FIGS. 11A-D.

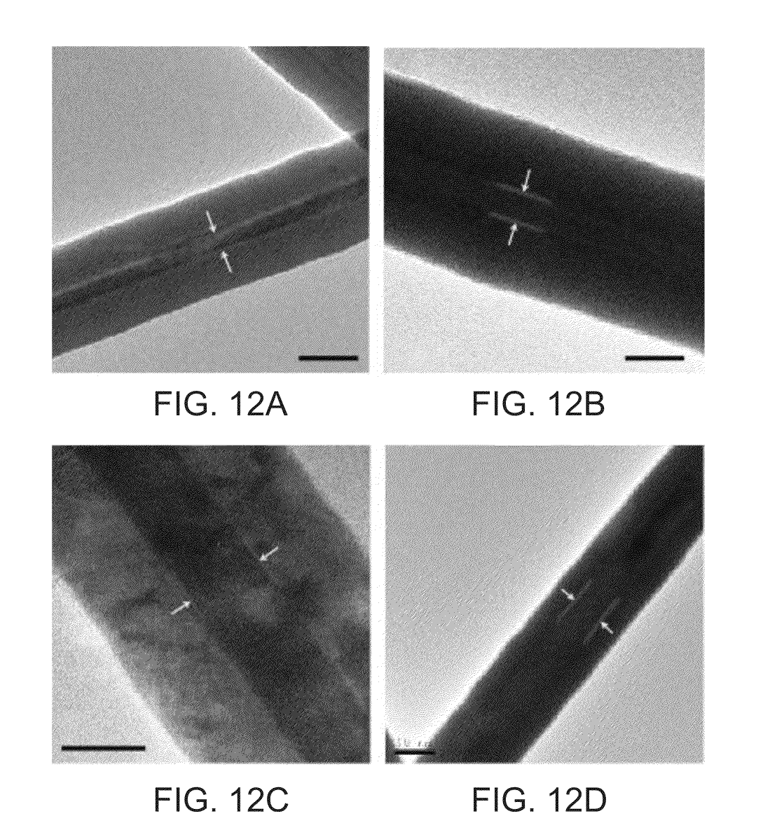

The effect of the gold nanoparticles diameter utilized on the shell morphology is demonstrated in FIGS. 12A-D.

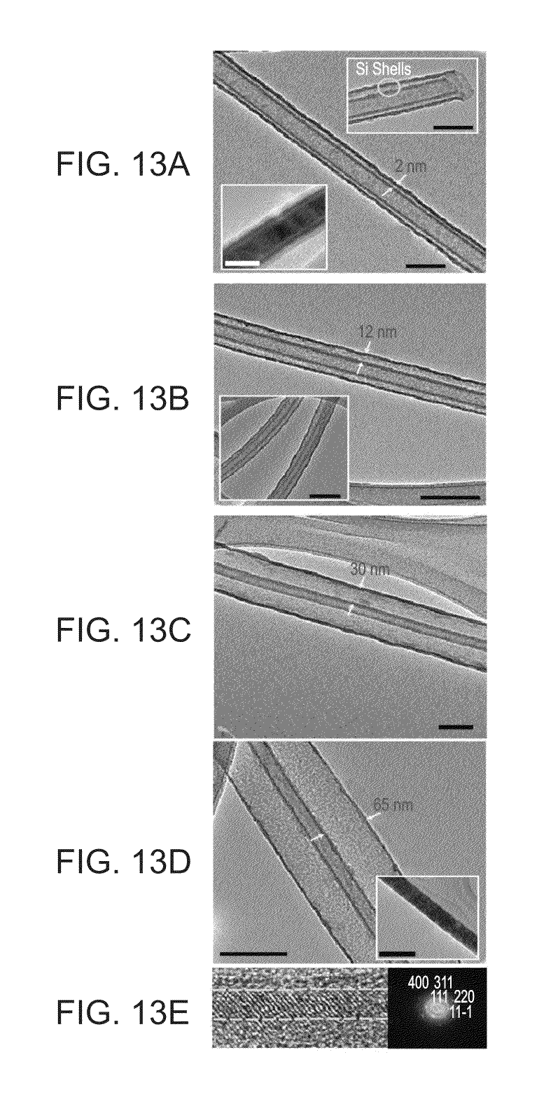

Selective extraction of the germanium core and shells from the core-multishell heterostructures leads to the formation of smooth, crystalline tube-in-tube structures with variable inter-wall distances, as shown in FIGS. 13A-D.

FIGS. 13A-D present a set of representative TEM micrographs of the obtained crystalline DWSiNTs-like structures with wall thickness of about 5 nm and with uniform and variable interwall distance of 2 nm (FIG. 13A), about 10 nm (FIG. 13B), 30 nm (FIG. 13C) and 60 nm (FIG. 13D), obtained for deposition times of 1, 2, 3 and 4 minutes, respectively, of the Ge shell.

FIG. 13A is a LRTEM image, of a DWSiNT-like structure with inter-wall distance of 2 nm and smooth and uniform walls thickness of 4 nm. Top inset is a LRTEM image, showing the open-ended nanotube. The white circle highlights the walls of the nanotubular structure. It should be noted that the nanotubular structures are open-ended and possess well-separated walls along nearly their entire length. Without being bound to any particular theory, it is suggested that the wall separation are a result of electrostatic repulsion between the native oxide-covered neighboring walls. Bottom inset is a LRTEM image, showing the morphology of the corresponding core-multishell structure. As seen in the bottom inset, the nanotubular structure is complementary to the morphology of the sacrificial germanium core/shell heterostructure.

FIG. 13B is a LRTEM image, of DWSiNT-like structure with inter-wall distance of about 10 nm. The inset is a LRTEM image, of the corresponding core-multishell structures with Ge-core size of about 10 nm.

FIG. 13C is a LRTEM image, of DWSiNT-like structure with inter-wall distance of about 30 nm.

FIG. 13D is a LRTEM image, of DWSiNTs-like structure with inter-wall distance of 60 nm. The inset is a LRTEM image, of the corresponding template.

Detailed HRTEM studies and the corresponding FFT analysis revealed that the resultant DWSiNT-like structures have a cell structure of a diamond cubic (FIG. 13E). In addition, representative energy-dispersive X-ray spectroscopy (EDX) spectra (data not shown), which are common to all of the prepared nanotubular structures, show less than 1% germanium impurities and a well-correlated silicon signal along the longitudinal axis of the nanotubes, further substantiating a successful preparation of multi-walled structures.

As described in detail hereinabove, the process of producing N-walled nanostructures in accordance to some embodiments of the present invention is advantageous as it enables a growth process during which the chemical composition of each wall of the nanotubes may be controlled. Such a production process enables the formation of nanotubular structures in which the walls are chemically differentiated simply by varying the inlet gas species during the growth.

Any of the modifications and manipulations described hereinabove for single-walled nanostructures can be applied for double-walled nanostructures and multi-walled nanostructures, using the process described in this example.

As an example, the process described herein may be used for forming DWSiNTs with an exterior n-type wall and an interior p-type wall, by introducing an n-dopant and a p-dopant during the deposition of the respective Si layer, in accordance with the procedure described, for example, in Example 3 hereinabove.

### Example 9

### Preparation of Modified Double-Walled Si Nanostructures and of a Device Containing Same

Device fabrication is carried out using the following methodology:

The heterostructured core-multi-layered Ge/Si nanostructures are deposited on a highly-doped silicon substrate (<0.005 Ω/cm) with a 600 nm-thick silicon oxide (SiO₂) dielectric layer.

In order to electrically address each silicon layer of the heterostructure, electrodes/contacts such as, for instance, Ni/Au source-drain electrodes/contacts are formed on every silicon layer. Thus, sequential e-beam lithography and germanium/silicon etching procedures are used for forming source-drain electrodes/contacts such as Ni/Au source-drain electrodes/contacts.

After the creation of metal contacts on each wall, selective removal of the remaining germanium sections is effected by immersion of the device substrate in a solution of hydrogen peroxide, as detailed hereinabove.

It should be noted that the sacrificial germanium interlayers are used as selective etch-stop layers between the silicon walls during the multifunctional fabrication process of transistors. This makes the electrical connection of each individual silicon wall, which is performed prior to the removal of the remaining of unetched germanium layers by selective chemical etching, relatively easy and controllable.

A relatively rapid thermal annealing (RTA; performed at 380° C. for 3 minutes) is thereafter performed, so as a to form a stable, conducting silicide with a low Schottky barrier.

FIG. 14A schematically illustrate a silicon double-walled nanotube-based dual transistor electrical device (field emitting device, FET), prepared as described hereinabove.

An exemplary such device was prepared from double-walled Si nanotubes in which the first silicon layer was deposited in the presence of a n-dopant (diborane (B₂H₆)) and the second silicon layer was deposited in the presence of a p-dopant (phosphine (PH₃)), so as to form a p-type exterior wall and an n-type interior wall, and altogether nanotubular structures with dual electrical properties. The n-type and p-type DWSiNTs were formed with different doping densities simply by changing the partial pressure of the reactants.

FIG. 14B is a LRTEM image, of DWSiNT-like structure, in which the exterior wall is p-type doped and the interior wall is n-type doped.

Electrical measurements of the FET fabricated from a p-type outer/n-type inner DWSiNT were performed. In these measurements, a back-gate electrode was used to modulate the electrostatic potential of the double-walled nanotubular structure while current versus voltage profiles were measured separately for each wall. Variations in the conductance vs. gate voltage profiles of each wall was used to distinguish whether a given nanowire is p-type or n-type.

FIGS. 14C-F are comparative plots presenting the electrical measurements of dual-performance p/n type nanotransistor devices. FIGS. 14C and 14D correspond to the outer p-type wall FET and FIGS. 14E and 14F correspond to the Inner n-type wall FET.

FIG. 14C shows the current (I_{sd}) versus drain-source bias (V_{sd}) (output characteristics) of an outer p-type wall FET at various gate voltages (V_{g}). The current (I_{sd}) versus drain-source bias (V_{sd}) profiles are plotted against various gate voltages (V_{g}) of: −5V (red), −3V (purple), −1 V (blue), +1V (sky blue) +3 V (green) and +5 V (light purple). FIG. 14D shows the current variation as a function of the applied gate voltage (V_{g}) at constant V_{sd} of +5 V.

FIG. 14E are comparative plots presenting the current (I_{sd}) versus drain-source bias (V_{sd}) (output characteristics) of an inner n-type wall FET at various gate voltages (V_{g}). The current (I_{sd}) versus drain-source bias (V_{sd}) profiles are plotted against various gate voltages (V_{g}) of: 5 V (pink), 3 V (red), 1 V (blue), 0 V (green), −1V (black) −3V (yellow), and −5 V (light blue).

FIG. 14F illustrates the current variation as a function of the applied gate voltage (V_{g}) at constant V_{sd} of +1 V.

The data presented in FIGS. 14C-14F clearly demonstrate that the boron-doped (n-doped) and phosphorus-doped (p-doped) walls of the double-walled silicon nanotube structure behave as p-type and n-type electrical elements, respectively. P-type and n-type walls yield average transconductances values of 700 nS and 520 nS, respectively, at these specific doping levels (1:800 B:Si and 1:800 P:Si, respectively). Those values are comparable to the performance of silicon nanowires devices using similar experimental conditions [see, for example, Cui et al. J. Phys. Chem. B 104, 5213-5216 (2000); and Zheng et al. Adv. Mater. 16, 1890-1894 (2004)]. Also, the doping level at each wall can be separately controlled so as to achieve the electrical characteristics required.

Clearly, intriguing multifunctional electrical nanodevices of complex performance can be fabricated using a single nanotubular building block with known number of electrically independent wall elements. This approach may be easily expanded to fabricate electrical devices of enhanced complexities using single hybrid nanotubular multi-walled structures consisting of a larger amount of walls where each wall is having its own physical and electrical properties.

### Example 10

### Preparation and Structural Characterization of Multi-Walled Si Nanostructures

Using the methodology described in Example 8 hereinabove, multi-walled silicon nanotubes were prepared, by sequentially depositing Ge and Si shells and thereafter etching the Ge layers.

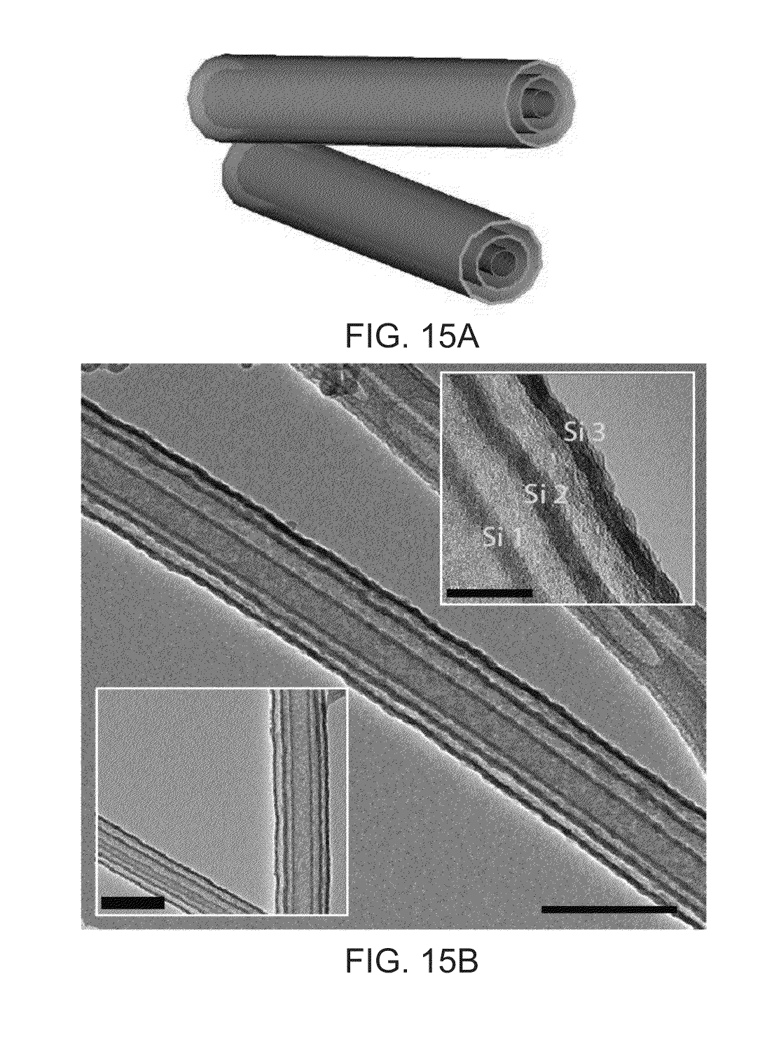

FIGS. 15A and 15B present a schematic illustration of a triple-walled nanotubular structure (triple-walled SiNTs) according to some embodiments of the invention (FIG. 15A) and its corresponding LRTEM image, on a scale bar of 100 nm (FIG. 15B). As shown in FIG. 15B, the triple-walled nanotubular structure has smooth and uniform walls and a relatively uniform interwall distance along its entire length. The top inset is a magnified HRTEM image, of the triple-walled SiNTs, and the bottom inset is a LRTEM image of the triple-walled SiNTs, both demonstrating that the triple-walled nanotubular structure possesses sharp boundaries between its shells.

Introduction of dopants and other reactants to the silicon shells can be effected, so as to impart the nanotubes variable properties, if desired. The above process can therefore further involve the formation of nanotubes with variant composition, in some or all of the formed nanotubes in the multi-walled nanostructures. For example, p-type/m-type silicon shells are prepared by feeding the CVD system simultaneously with 5 sccm diborane and 5 sccm phosphine, and 5 sccm silane (SiH₄) during the shell growth step and are to be processed at 450° C. and 1 Torr. Other modifications of the shape and/or chemical composition of each or all of the layers can be effected according to the procedures described herein.

The space between the walls can be determined between each pair of subsequent walls by the deposition time of the Ge shell between the walls, and/or by forming Ge layers with reduced and/or enhanced thickness as described in Examples 2 hereinabove.

### Example 11

### Preparation and Structural Characterization of Wire-in-Tube Si Nanostructures

The methodology described herein has been extended to produce unique hybrid nanotubular structures: silicon nanowire (SiNW) within silicon nanotubes, which are also referred to herein as wire-in-tube nanostructures.

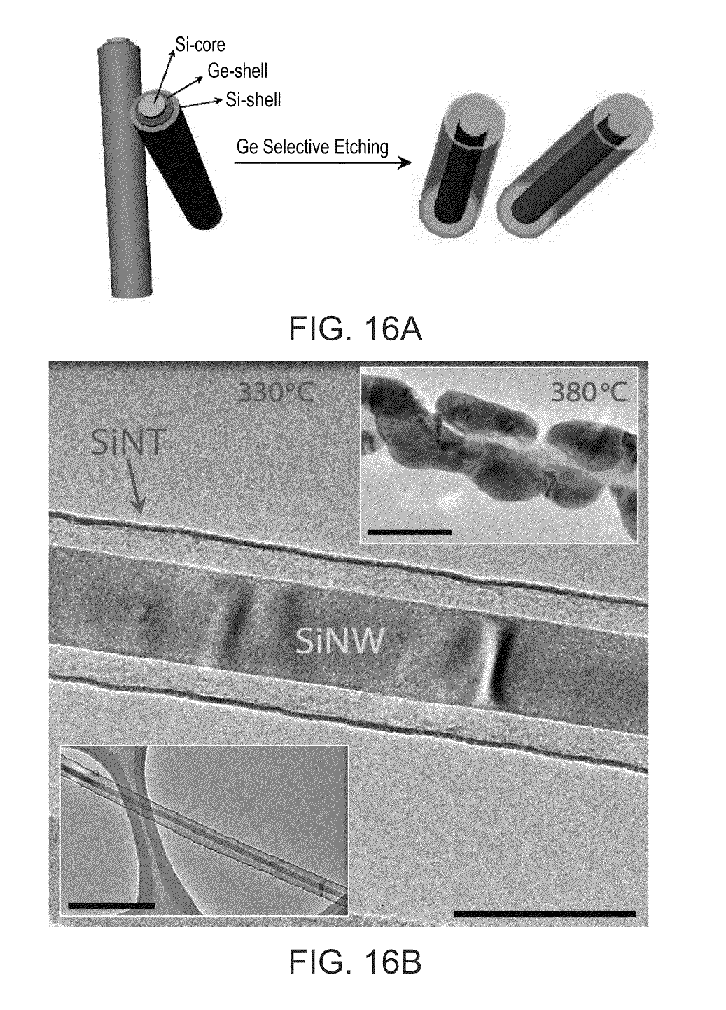

FIG. 16A presents a schematic illustration of a process of preparing Si nanowire-in-nanotube. Silicon nanowire cores are formed and coated with Ge shells, followed by deposition of a silicon shell to give Si (core)-Ge—Si (multishell) nanowires. Selective Ge etching results in the desired nanostructures.

The methodology described in Example 1 hereinabove for the formation of Ge cores 1 is used herein for forming Si cores.

Accordingly, Au nanoclusters with a desired diameter, such as, for instance, of 20 nm, are deposited on a substrate, e.g., a Si (100) substrates, from a colloidal solution. The diameter of the gold nanoparticles defines the diameter of the Si core.

The growth substrate is thereafter placed into a chemical vapor deposition system (CVD), as described hereinabove. The first CVD step involves the formation of a Si core template using silane (SiH₄) as a precursor and an H₂/Argon mixture as carrier gas, at 460° C. (5 sccm silane (Sin₄) in 10 sccm Ar at 25 Torr], for forming the Si core template. Thereafter, in the second CVD step, germanium (50 sccm (GeH₄) is introduced to the CVD and processed at 100 Torr, and at an increased temperature of 330° C. It should be noted that it was found that at a temperature higher than 330° C., the growth of germanium shells follows an S-K mechanism, to give well-separated 3D clusters.

In subsequent CVD steps, the deposition of Si shells on top of Ge shells and the deposition of Ge shells on top of Si shells are effected repeatedly and interchangeably, as desired, to allow conformal homogeneous vapor-phase deposition and the formation of a Si nanowire within Si single-walled, double-walled or multi-walled nanotubes. The deposition of germanium shells is performed for different periods of time, depending on the desired distance between the core (Si)-shell (Si) and the Shell (Si)-Shell-(Si). Since the Ge shells possess poorly crystalline/amorphous structure, the shells are crystallized by a series of annealing procedures. In order to prevent degradation of the conformal smooth germanium shells, the annealing procedures are carried out at a temperature between 330° C. and 450° C.].

Introduction of dopants and other reactants to the silicon shells can be effected, so as to impart the formed nanostructures variable properties, if desired. The above process can therefore further involve the formation of nanotubes with variant composition, in some or all of the formed nanotubes in the multi-walled nanostructures. For example, p-type/m-type silicon shells are prepared by feeding the CVD system simultaneously with 5 sccm diborane and 5 sccm phosphine, and 5 sccm silane (SiH₄) ((together with 10 sccm H₂ and 5 sccm Ar as carrier gases) during the shell growth step and are to be processed at 450° C. and 1 Torr. Other modifications of the shape and/or chemical composition of each or all of the layers can be effected according to the procedures described herein.

It should be noted that the formation of uniform and smooth germanium shells on silicon nanowires with no limiting dimensions such as shell thickness and core diameter is firstly reported herein.

Once sequential depositions are completed, the resultant nanowire heterostructures are chemically etched with H₂O₂ to selectively etch the germanium shell(s) and to form Si nanowire-in-nanotube hybrid structures.

FIG. 16B is a LRTEM image, of a silicon nanowire being 80 nm in diameter within a uniform and smooth silicon nanotube. Bottom inset is a LRTEM image, of a hybrid nanowire-in-nanotube with a silicon nanowire of 20 nm diameter, showing that the Si nanowire-Si nanotube distance is relatively uniform along the entire length (tens of microns) of the nanotubular structure, presumably due to electrostatic repulsion, as discussed hereinabove.

Upper inset is a LRTEM image is taken after deposition of a Ge shell on top of Si nanowire at a high temperature of 380° C., that the obtained structure has a highly nonuniform structure.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1.-49. (canceled)

50. A multi-walled tubular nanostructure made of at least one single-crystalline inorganic substance, the nanostructure being characterized by an interwall distance between at least two walls which is smaller than 10 nm.

51. The multi-walled tubular nanostructure of claim 50, wherein an interwall distance between all of the walls is identical.

52. The multi-walled tubular nanostructure of claim 50, wherein an interwall distance between at least two pairs of adjacent walls is different.

53. The multi-walled tubular nanostructure of claim 50, being further characterized by a different wall thickness of at least two walls.

54. The multi-walled tubular nanostructure of claim 50, being further characterized by a different chemical composition of at least two walls.

55. The tubular nanostructure of claim 50, further comprising a nanowire interposed within an inner wall of the nanostructure.

56. The tubular nanostructure of claim 50, wherein said single-crystalline inorganic substance is single-crystalline silicon.

57. A multi-walled, tubular single-crystalline silicon nanostructure.

58. The tubular silicon nanostructure of claim 57, further comprising a nanowire interposed within an inner wall of the nanostructure.

59. A single-walled tubular nanostructure made of at least one single-crystalline inorganic substance, the nanostructure being characterized by an inner diameter which is either smaller than 5 nm or greater than 100 nm.

60. The single-walled nanostructure of claim 59, wherein the nanostructure further comprises at least one additional substance and/or is surface-modified.

61. The tubular nanostructure of claim 59, further comprising a nanowire interposed within an inner wall of the nanostructure.

62. The tubular nanostructure of claim 59, wherein said single-crystalline inorganic substance is single-crystalline silicon.

63. A method of producing single-walled or multi-walled tubular, inorganic, single-crystalline nanostructures, the method comprising:
growing a nanowire made of a crystalline, sacrificial substance;
epitaxially growing, onto said nanowire, a layer of an inorganic substance that has a crystallinity mismatch with said sacrificial substance of less than 4.5%; and
etching said nanowire, thereby producing a single-walled tubular, inorganic, single-crystalline nanostructure,
whereas when the nanostructure is a multi-walled nanostructure, the method further comprising, prior to said etching:
growing onto said layer of said inorganic substance a layer of said sacrificial substance;
epitaxially growing, onto said layer of said sacrificial substance, a layer of said inorganic substance; and
repeatedly growing onto an outer layer of said inorganic substance a layer of said sacrificial substance; and growing onto said layer of sacrificial substance said layer of said inorganic substance; and
whereas said etching comprises etching said nanowire and each of said layers of said sacrificial substance,
the method being such that at least one of a shape, diameter, wall thickness and chemical composition of each wall is reproducibly controlled.

64. The method of claim 63, wherein said semiconductor substance is silicon.

65. The method of claim 63, wherein said sacrificial substance is germanium.

66. The method of claim 64, wherein said sacrificial substance is germanium.

67. The method of claim 65, wherein growing said germanium nanowire comprises a chemical vapor deposition (CVD) performed at conditions that affect axial growth of said nanowire.

68. The method of claim 63, wherein growing said nanowire template comprises a chemical vapor deposition (CVD) performed at conditions that affect conformal growth of said nanowire.

69. The method of claim 63, wherein growing said nanowire template comprises a first chemical vapor deposition (CVD) performed at conditions that affect conformal growth of said nanowire, followed by a second chemical vapor deposition (CVD) performed at conditions that affect axial growth of said nanowire.

70. The method of claim 63, further comprising, prior to said epitaxially growing said layer of said inorganic substance, reducing a diameter of said nanowire.

71. The method of claim 70, wherein said sacrificial substance is germanium and wherein reducing said diameter is effected by thermal oxidation.

72. The method of claim 63, further comprising, prior to epitaxially growing said layer of said inorganic substance, increasing an average inner diameter of said nanowires.

73. The method of claim 72, wherein increasing said average inner diameter is performed by depositing an external layer of said sacrificial substance onto said nanowire.

74. The method of claim 63, wherein said nanostructures are single-walled nanostructure and wherein epitaxially growing said layer of said inorganic substance is effected in a presence of an additional substance, to thereby obtain tubular nanostructures which comprise a mixture of said inorganic substance and said additional substance.

75. The method of claim 63, wherein said nanostructures are multi-walled nanostructures and wherein epitaxially growing at least one layer of said inorganic substance is effected in a presence of at least one additional substance, to thereby obtain at least one wall which comprises a mixture of said inorganic substance and said additional substance.

76. The method of claim 63, further comprising, subsequent to epitaxially growing said layer of said inorganic substance, chemically modifying at least a portion of a surface of an outer layer of said inorganic substance.

77. The method of claim 63, further comprising chemically modifying at least a portion of an internal surface of said nanostructures.

78. The method of claim 63, wherein said nanostructures are multi-walled nanostructures and wherein growing each of said layers of said sacrificial substance comprises a CVD performed at conditions that affect formation of a conformal, non-crystalline layer of said sacrificial substance.

79. The method of claim 78, further comprising, subsequent to said CVD, annealing said conformal, non-crystalline layer of said sacrificial substance, to thereby obtain a layer of a single-crystalline sacrificial substance.

80. Single-walled inorganic, single-crystalline tubular nanostructures prepared by the method of claim 63.

81. Multi-walled inorganic, single-crystalline tubular nanostructures prepared by the method of claim 63.

82. A method of preparing a single-walled or a multi-walled single crystalline inorganic nanostructure having an inorganic nanowire interposed within an inner wall of the nanostructure, the process comprising:
growing a nanowire made of an inorganic substance;
growing a layer of a sacrificial substance onto the nanowire;
epitaxially growing a layer of an inorganic substance onto the layer of the sacrificial substance; and
etching the sacrificial substance, to thereby obtain the single-walled nanostructure having the nanowire interposed therewithin, wherein when the nanostructure is a multi-walled nanostructure, the method further comprising, prior to said etching:
growing onto said layer of said inorganic substance a layer of said sacrificial substance;
epitaxially growing, onto said layer of said sacrificial substance, a layer of said inorganic substance; and
repeatedly growing onto an outer layer of said inorganic substance a layer of said sacrificial substance; and growing onto said layer of sacrificial substance said layer of said inorganic substance; and
whereas said etching comprises etching each of said layers of said sacrificial substance, thereby obtaining the multi-walled nanostructure having the nanowire interposed within an inner wall.

83. A device comprising the tubular nanostructure of claim 50.

84. An electric device, comprising the nanostructure of claim 50, wherein said electric device comprises at least one of a transistor, a field effect transistor, an inverter, a switch and a sensor.

85. A nanofluidic device, comprising the nanostructure of claim 50, wherein said nanofluidic device comprises at least one of a nanofluidic transistor device, a liquid separator and a liquid analyzer.

86. A device comprising the tubular nanostructure of claim 57.

87. An electric device, comprising the nanostructure of claim 57, wherein said electric device comprises at least one of a transistor, a field effect transistor, an inverter, a switch and a sensor.

88. A nanofluidic device, comprising the nanostructure of claim 57, wherein said nanofluidic device comprises at least one of a nanofluidic transistor device, a liquid separator and a liquid analyzer.

89. A device comprising the tubular nanostructure of claim 59.

90. An electric device, comprising the nanostructure of claim 59, wherein said electric device comprises at least one of a transistor, a field effect transistor, an inverter, a switch and a sensor.

91. A nanofluidic device, comprising the nanostructure of claim 59, wherein said nanofluidic device comprises at least one of a nanofluidic transistor device, a liquid separator and a liquid analyzer.

92. A device comprising the tubular nanostructure of claim 80.

93. An electric device, comprising the nanostructure of claim 80, wherein said electric device comprises at least one of a transistor, a field effect transistor, an inverter, a switch and a sensor.

94. A nanofluidic device, comprising the nanostructure of claim 80, wherein said nanofluidic device comprises at least one of a nanofluidic transistor device, a liquid separator and a liquid analyzer.

95. A device comprising the tubular nanostructure of claim 81.

96. An electric device, comprising the nanostructure of claim 81, wherein said electric device comprises at least one of a transistor, a field effect transistor, an inverter, a switch and a sensor.

97. A nanofluidic device, comprising the nanostructure of claim 81, wherein said nanofluidic device comprises at least one of a nanofluidic transistor device, a liquid separator and a liquid analyzer.
